(19) United States
(12) Patent Application Publication
(10) Pub. No.: US 2018/0212184 A1
(43) Pub. Date: Jul. 26, 2018

(54) ORGANIC ELECTROLUMINESCENT ELEMENT

(71) Applicant: Konica Minolta, Inc., Tokyo (JP)

(72) Inventors: Toshiya KONDO, Hino-shi, Tokyo (JP); Hiromoto II, Machida-shi, Tokyo (JP); Shigeru KOJIMA, Hino-shi, Tokyo (JP)

(21) Appl. No.: 15/746,297

(22) PCT Filed: Jul. 12, 2016
(86) PCT No.: PCT/JP2016/070500

§ 371 Date: Jan. 19, 2018

(30) Foreign Application Priority Data
Sep. 30, 2015 (JP) 2015-192647

(51) Int. Cl. H01L 51/52; G02B 1/11; H01L 51/00

(52) U.S. Cl. CPC H01L 51/5234; G02B 1/11; H01L 51/5206; H01L 51/5281; H01L 51/5253; H01L 51/0097

(57) ABSTRACT

An object of the present invention is to provide an organic electroluminescent element which is excellent in high-temperature resistance, bending resistance, and light transmittance. The organic electroluminescent element according to the present invention includes an organic functional layer, which includes a light emitting layer interposed by a pair of transparent electrodes, between an element substrate and a sealing substrate, wherein both the element substrate and the sealing substrate have a gas barrier layer, and an anti-reflection film is laminated on the surface at a light emission side of at least one of the element substrate and the sealing substrate via a pressure-sensitive adhesive layer.

### TECHNICAL FIELD

The present invention relates to an organic electroluminescent element. More specifically, the present invention relates to an organic electroluminescent element having improved performance such as high-temperature resistance.

### BACKGROUND ART

Organic electroluminescent elements (hereinafter, also referred to as organic EL elements or OLEDs) utilizing electroluminescence (hereinafter, referred to as EL) of organic materials are thin-film type complete solid elements that can emit light at low voltages of from about several volts to several tens of volts, and have many excellent features such as high luminance, high light emitting efficiency, thin type, and light weight. Therefore, organic electroluminescent elements have gained attention in recent years as backlights for various displays, display plates such as signboards and emergency lights, and surface light emitters such as illumination light sources.

In particular, recently, double-sided emission type organic EL elements have gained attention (for example, see Patent Literature 1). Of the double-sided emission types, particularly, the use of a so-called transparent organic EL element (transparent organic light-emitting device: TOLED), which is transparent during non-emission of light, in windows of buildings, windows of vehicles such as automobiles and aircraft, transparent displays, and the like is underway. In particular, flexible transparent organic EL elements can change the shape thereof and can also be applied to curved surfaces and the like. Thus, the flexible transparent organic EL elements are under examination.

However, gas barrier properties are essential in the flexible organic EL element in which a resin base material is used for an element substrate or a sealing substrate. Thus, various studies on ensuring of sufficient gas barrier properties have been conducted (for example, see Patent Literature 2).

In particular, a laminate gas barrier layer in which a plurality of gas barrier layers are laminated is effective, but there is a problem in that light transmittance is decreased due to the lamination of the gas barrier layers. In addition, there is a problem in high-temperature environment resistance in summer, for example, in the case of application to windows.

Further, in order to ensure the light transmittance, studies on application of an external light reflection preventing means have been conducted. Accordingly, the light transmittance at the time of turning off a light can be improved. However, a method using embossment, anti-reflection film coating, or the like has problems such as a large number of production processes and a large cost burden.

On the other hand, with respect to these methods, for example, a method of bonding an anti-reflection film is disclosed in Patent Literature 3. This method is an effective means in terms of a relatively small number of production processes and low cost. However, there are problems in terms of high-temperature resistance and high light transmittance.

As a bonding means, a thermosetting adhesive, an ultraviolet curable adhesive, or the like is mentioned, but these adhesives are relatively expensive. Further, in the curable adhesive, cracks or peeling-off easily occurs at the bonding interface at a high temperature due to a difference in thermal expansion rate. In addition, when an electroluminescent element is maintained in a bending state, cracks or peeling-off also occurs easily. Furthermore, air bubbles are liable to be formed at a portion where cracks occur or a peeled-off portion, which causes a decrease in light transmittance.

### CITATION LIST

### Patent Literature

Patent Literature 1: JP 2008-533655 A

Patent Literature 2: JP 2014-226894 A

Patent Literature 3: JP 2012-527084 A

### SUMMARY OF INVENTION

### Technical Problem

The present invention is made in view of the above-described problems and circumstances, and an object thereof is to provide an organic electroluminescent element which is excellent in high-temperature resistance, bending resistance, and light transmittance.

### Solution to Problem

The present inventors have conducted studies on causes of the above-described problems in order to solve the above-described problems. As a result, it is found that by laminating an anti-reflection film via a pressure-sensitive adhesive layer, an organic electroluminescent element of the present invention can improve high-temperature resistance, bending resistance, and light transmittance, and thus the present invention has been attained.

That is, the above-described problems are solved by the following means.

1. A flexible organic electroluminescent element comprising an organic functional layer, which includes a light emitting layer interposed by a pair of transparent electrodes, between an element substrate and a sealing substrate,

wherein both the element substrate and the sealing substrate have a gas barrier layer, and

an anti-reflection film is laminated on the surface at a light emission side of at least one of the element substrate and the sealing substrate via a pressure-sensitive adhesive layer.

2. The organic electroluminescent element according to Item. 1,

wherein at least one of the pair of transparent electrodes is a transparent electrode which includes an undercoat layer containing a nitrogen-containing compound and an electrode layer containing silver as a main component on the undercoat layer.

3. The organic electroluminescent element according to Item. 2,

wherein the undercoat layer contains a compound satisfying a relation between interaction energies represented by the following Formula (1) and Formula (2).

ΔEef=n×ΔE/s Formula (1):

n: Number of nitrogen atom(s) (N) contained in compound and stably bonded with silver (Ag)

ΔE: Interaction energy between nitrogen atom (N) and silver (Ag)

s: Surface area of compound

−0.40≤ΔEef[kcal/mol·Å²]≤−0.10 Formula (2):

4. The organic electroluminescent element according to any one of Items. 1 to 3,

wherein at least one of the pair of transparent electrodes is a transparent electrode including a thin metal wire and a transparent conductive member.

5. The organic electroluminescent element according to Item. 4,

wherein the thin metal wire contains metal nanoparticles.

6. The organic electroluminescent element according to any one of Items. 1 to 5, wherein the anti-reflection film is laminated on the surfaces of the light emission sides of both of the element substrate and the sealing substrate via the pressure-sensitive adhesive layer.

7. The organic electroluminescent element according to any one of Items. 1 to 6,

wherein at least one of the gas barrier layers of the element substrate and the sealing substrate is two or more layers of the gas barrier layer, and

at least one layer of the two or more layers of the gas barrier layer is a gas barrier layer including a polysilazane modified layer.

### Advantageous Effects of Invention

According to the above-described means of the present invention, it is possible to provide an organic electroluminescent element which is excellent in high-temperature resistance, bending resistance, and light transmittance.

Although the mechanism by which effects of the present invention are expressed or the mechanism of action of the present invention has not been clarified, the mechanisms are presumed as follows.

In a case where the anti-reflection film is laminated on the surface at the light emission side of at least one of the element substrate and the sealing substrate, cracks or peeling-off easily occurs at the bonding interface at a high temperature due to a difference in thermal expansion rate between the element substrate or the sealing substrate and the anti-reflection film. In addition, when the electroluminescent element is maintained in a bending state, cracks or peeling-off also occurs easily. Further, air bubbles are liable to be formed at a portion where cracks occur or a peeled-off portion, and light scattering occurs due to the air bubbles. Thus, this is considered to cause a decrease in light transmittance.

Meanwhile, when the anti-reflection film is attached by using the pressure-sensitive adhesive, flexibility can be maintained even in a state where an organic functional layer or the like is bonded to a substrate, it is possible to suppress peeling-off at a high temperature and generation of air bubbles. According to this, it is presumed that a decrease in the light transmittance of the organic EL element can be suppressed.

### BRIEF DESCRIPTION OF DRAWINGS

FIG. 1 is a schematic cross-sectional view of an organic electroluminescent element of the present invention.

FIG. 2 is a schematic cross-sectional view of the organic electroluminescent element of the present invention.

FIG. 3 is a schematic cross-sectional view of the organic electroluminescent element of the present invention.

### DESCRIPTION OF EMBODIMENTS

An organic electroluminescent element of the present invention is a flexible organic electroluminescent element including an organic functional layer, which includes a light emitting layer interposed by a pair of transparent electrodes, between an element substrate and a sealing substrate, in which both the element substrate and the sealing substrate have a gas barrier layer, and an anti-reflection film is laminated on the surface at a light emission side of at least one of the element substrate and the sealing substrate via a pressure-sensitive adhesive layer. This feature is a technical feature that is common to or corresponds to the inventions according to respective claims.

Further, in the organic electroluminescent element of the present invention, at least one of the pair of transparent electrodes is a transparent electrode which includes an undercoat layer containing a nitrogen-containing compound and an electrode layer containing silver as a main component on the undercoat layer, which is preferable from the viewpoint that a balance between a high light transmittance and a high light emitting efficiency can be achieved.

Further, in the organic electroluminescent element, the undercoat layer preferably contains a compound satisfying a relation between interaction energies represented by the following Formula (1) and Formula (2).

The reason for this is as follows. The silver atom that constitutes the electrode layer containing silver as a main component interacts with a nitrogen-containing compound that constitutes the undercoat layer so that the silver atom is reduced in diffusion length at the undercoat layer surface and thus aggregation of silver is suppressed. Therefore, a thin silver film is formed in a monolayer growth mode (Frank-van der Merwe: FW mode) although, in general, silver can easily form islands due to nuclear growth mode (Volumer-Weber: VW mode). Thus, the metal layer can be obtained with a uniform thickness even when it has a small thickness.

Further, in particular, the effective action energy ΔEef shown in the above Formula (1) is defined as the interaction energy between the nitrogen-containing compound that constitutes the undercoat layer and silver that constitutes the electrode layer containing silver as a main component, and a compound whose value satisfies a specific range is used to constitute the undercoat layer. Thus, it becomes possible to reliably achieve the effect of “suppressing aggregation of silver.” The reason for this is that a metal layer having an extremely small film-thickness yet having favorable adhesiveness on the undercoat layer, being less likely to be peeled off at a high temperature or at the time of bending, and having a low sheet resistance is formed.

Further, in the organic electroluminescent element of the present invention, at least one of the pair of transparent electrodes is a transparent electrode including a thin metal wire and a transparent conductive member, which is preferable from the viewpoint that a balance between a high light transmittance and a high light emitting efficiency can be achieved.

Further, in the organic electroluminescent element of the present invention, the thin metal wire contains metal nanoparticles, which is preferable since flexibility of the thin metal wire is enhanced, breaking down of wires is less likely to occur at a high temperature or at the time of bending, and sufficient conductivity can be maintained.

Further, the anti-reflection film is laminated on the surfaces at the light emission sides of both of the element substrate and the sealing substrate via the pressure-sensitive adhesive layer, which is preferable since an effect of suppressing scattering of transmitted light at the light emission sides of both the substrates is obtainable.

Further, at least one of the gas barrier layers of the element substrate and the sealing substrate is two or more layers of the gas barrier layer, and at least one layer of the two or more layers of the gas barrier layer is a gas barrier layer including a polysilazane modified layer, which is preferable from the viewpoint that gas barrier properties and flexibility are excellent and cracks or peeling-off is less likely to occur at a high temperature or at the time of bending.

Hereinafter, the present invention and the constitution elements thereof, as well as configurations and embodiment for carrying out the present invention, will be described in detail. Incidentally, in the following description, when two figures are used to indicate a range of value before and after “to,” these figures are included in the range as a lower limit value and an upper limit value.

<<Organic EL Element>>

The organic EL element of the present invention is a flexible organic electroluminescent element including an organic functional layer, which includes a light emitting layer interposed by a pair of transparent electrodes, between an element substrate and a sealing substrate, in which both the element substrate and the sealing substrate have a gas barrier layer, and an anti-reflection film is laminated on the surface at a light emission side of at least one of the element substrate and the sealing substrate via a pressure-sensitive adhesive layer.

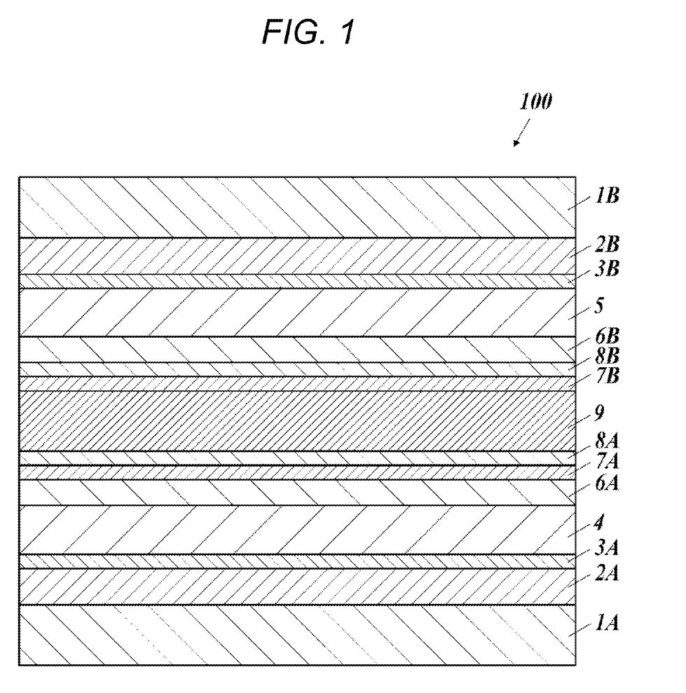

Specifically, as an exemplary configuration of an organic EL element 100 of the present invention, as illustrated in FIG. 1, the organic EL element 100 is preferably a double-sided emission type transparent organic electroluminescent element including an anti-reflection film 1A, a pressure-sensitive adhesive layer 2A, an antistatic layer 3A, an element substrate 4, a gas barrier layer 6A, an undercoat layer 7A, a transparent electrode 8A, an organic functional layer 9, an undercoat layer 7B, a transparent electrode 8B, a gas barrier layer 6B, a sealing substrate 5, an antistatic layer 3B, a pressure-sensitive adhesive layer 2B, and an anti-reflection film 1B.

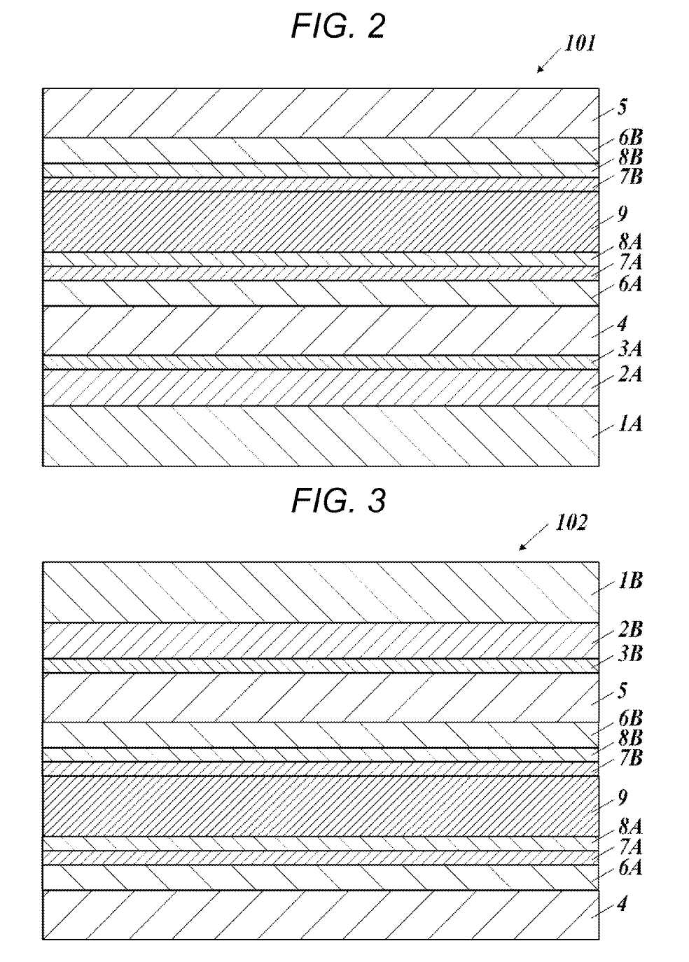

Further, as in organic EL elements 101 and 102 of the present invention illustrated in FIGS. 2 and 3, the pressure-sensitive adhesive layer 2A (2B), the antistatic layer 3A (3B), and the anti-reflection film 1A (1B) may be provided only on any one of the sealing substrate 5 side and the element substrate 4 side.

First, the anti-reflection film, the pressure-sensitive adhesive layer, the element substrate, and the sealing substrate will be described.

[Anti-Reflection Film]

The anti-reflection (AR) film according to the present invention is an optical film in which reflected light intensity is reduced by utilizing optical interference, and since the light transmittance is increased, contrast is improved, and scattering of transmitted light does not occur, there is also no decrease in resolution of an image.

Incidentally, the AR film according to the present invention is not an anti-glare (AG) film in which reflection is prevented by inputting particles in a hard coat resin and utilizing diffusion of reflected light using the unevenness formed on the surface and an internal diffusion due to a difference between the refractive index of the hard coat resin and the refractive index of the particle. The AG film has disadvantages of a decrease in contrast due to the diffusion of reflected light and a decrease in light transmittance due to the diffusion of transmitted light, which is not preferable in the present invention.

Optical interference layers in the AR film according to the present invention are preferably laminated such that reflectance is reduced by optical interference, in consideration of the refractive index, the thickness, the number of layers, the order of layers, and the like. The optical interference layer is preferably formed by a low refractive index layer having a lower refractive index than that of the support or a combination of a high refractive index layer having a higher refractive index than that of the support and the low refractive index layer. An optical interference layer formed from three or more layers of the refractive index layer is particularly preferable, and an optical interference layer in which three layers each having a different refractive index are laminated from the support side in order of the middle refractive index layer (a layer having a higher refractive index than that of support/a lower refractive index than that in high refractive index layer/low refractive index layer. Further, an anti-reflection layer having a layer structure of four or more layers is also preferably used in which two or more layers of the high refractive index layer and two or more layers of the low refractive index layer are alternatively laminated.

Although the following structure may be considered as a layer structure of the AR film according to the present invention, the present invention is not limited to these structures.

Resin base material/low refractive index layer

Resin base material/middle refractive index layer/low refractive index layer

Resin base material/middle refractive index layer/high refractive index layer/low refractive index layer

Resin base material/high refractive index layer (conductive layer)/low refractive index layer

Resin base material/anti-glare layer/low refractive index layer

The AR film according to the present invention preferably has a hard coat layer, and in this case, although the following structure may be considered, the present invention is not limited to these structures.

Resin base material/hard coat layer/low refractive index layer

Resin base material/hard coat layer/middle refractive index layer/low refractive index layer

Resin base material/hard coat layer/middle refractive index layer/high refractive index layer/low refractive index layer

Resin base material/hard coat layer/high refractive index layer (conductive layer)/low refractive index layer

Resin base material/hard coat layer/anti-glare layer/low refractive index layer

The low refractive index layer preferably contains silica fine particles, and has a refractive index which is lower than the refractive index of the resin base material serving as a support, and is preferably in a range of 1.30 to 1.45 as measured at 23° C. with a wavelength of 550 nm.

The thickness of the low refractive index layer is preferably 5 to 500 nm, further preferably 10 to 300 nm, and most preferably in a range of 30 to 200 nm.

Regarding a low refractive index layer forming composition, as silica fine particles, particularly, it is preferable to contain at least one kind or more of particles each of which has an outer shell layer and a porous or hollow structure at the inside thereof. Particularly, particles with an outer shell layer and a porous or hollow structure at the inside thereof are preferably hollow silica fine particles.

Incidentally, an organic silicon compound represented by the following general formula (OSi-1) or a hydrolysate thereof, or together with a polycondensation thereof may be contained in the low refractive index layer forming composition.

General Formula (OSi-1): Si(OR)₄

In the organic silicon compound represented by the above general formula, R in the formula represents an alkyl group having 1 to 4 carbon atoms. Specifically, tetramethoxysilane, tetraethoxysilane, tetraisopropoxysilane, and the like are preferably used.

In addition thereto, a solvent, as necessary, a silane coupling agent, a curing agent, a surfactant, and the like may be added.

A method for producing an optical interference layer of the AR film includes a dry method and a wet method. Examples of the dry method include a vacuum vapor deposition and a sputtering method, and in the display application, a metal oxide thin film having strong surface properties is formed in many cases. The dry method is conventionally batch treatment, but in recent years, a method of performing a continuous treatment on a film is also put to practical use. However, facility cost is high and productivity is low so that the dry method is extremely expensive. Examples of the wet method include batch treatment such as spin coating or dipping, and a coating method capable of continuously performing treatment such as a gravure coating. The spin coating and dipping are used as AR treatment for CRT, but with planarization of various displays, there is a strong demand that the size of the AR film is increased and the cost of the AR film is decreased. AR films formed by the coating method capable of continuously performing treatment have an advantage in low cost and supply performance, but AR films which have been commercially available are inferior to the dry method in light reflectance and surface properties.

The AR film according to the present invention is preferably an optical film having a moth-eye structure. The optical film having a moth-eye structure is an optical film in which conical microprotrusions are regularly arranged on the base material surface at a pitch of about 100 to several hundreds of nm. Application of various methods including a method using anode oxidation of aluminum, ion beam processing, press embossing, and rubbing are reviewed. A material of the base material preferably has a refractive index close to that of a material having a moth-eye structure to be formed, and PET, TAC, and the like are used in many cases. A variety of investigations on the height, the shape, and the production method of the moth-eye structure are currently underway according to objects, use purposes, and the like.

[Pressure-Sensitive Adhesive Layer]

An adhesive used in the pressure-sensitive adhesive layer according to the present invention is not a curing type adhesive thermally cured or cured by ultraviolet irradiation to obtain adhesive force but is a pressure-sensitive adhesive which adheres by pressing and in which curing of an adhesive portion does not occur at this time.

The pressure-sensitive adhesive according to the present invention has cohesion force and elasticity and further has stable adhesiveness for a long period of time. In particular, the pressure-sensitive adhesive does not need force such as heat or a solvent and can be attached to a target object with also utilizing an anchor effect by a small pressure. The cohesion force described herein corresponds to a force with which the adhesive resists internal fraction, and the elasticity described herein corresponds to a property in which an object, which has been applied with external force to change the shape or volume thereof, returns to the original state when the force is removed.

Owing to the cohesion force and the elasticity of the pressure-sensitive adhesive, the pressure-sensitive adhesive exert significant function as the stress alleviating function when stress is applied to the anti-reflection film or the gas barrier layer itself and can prevent excessive stress from being applied to the anti-reflection film or the gas barrier layer. In order to sufficiently exert the above effect, an adhesive force of the pressure-sensitive adhesive is preferably within a range of 3 to 20 [N/25 mm] in JIS Z0237-2009.

The type of the pressure-sensitive adhesive used in the present invention is not particularly limited, and examples thereof include urethane-based adhesives, epoxy-based adhesives, aqueous polymer-isocyanate-based adhesives, acryl-based adhesives, polyether methacrylate type adhesives, ester-based methacrylate type adhesives, oxidized type polyether methacrylate type adhesives, rubber-based adhesives, vinyl ether-based adhesives, and silicon-based adhesives. Examples of the type include solvent, emulsion, hot-melt, and so on.

It is desirable to perform attachment with a pressure-sensitive adhesive having a high light transmittance, and thus an acryl-based pressure-sensitive adhesive having a high transparency and strong adhesive force is preferable. Further, an antistatic agent or various fillers may be mixed in the pressure-sensitive adhesive by using a well-known method.

In order to improve adhesive properties of the acryl-based resin, various additives, for example, tackifiers, such as a natural resins (such as rosin), modified rosin, derivatives of rosin and modified rosin, polyterpene-based resins, terpene modification products, aliphatic hydrocarbon resins, cyclopentadiene-based resins, aromatic petroleum resins, phenolic resins, alkyl-phenol-acetylene-based resins, coumarone-indene-based resins, and vinyltoluene-a-methylstyrene copolymers, anti-aging agents, stabilizing agents, softening agents, and the like can be added as necessary. These can also be used in combination of two or more kinds thereof as necessary. Further, in order to improve light resistance, an organic ultraviolet absorber such as benzophenone-based ultraviolet absorber or a benzotriazole-based ultraviolet absorber can be added to the adhesive.

A method for forming the pressure-sensitive adhesive layer is not particularly limited, and examples thereof include general methods such as a gravure coater, a micro gravure coater, a comma coater, a reverse roll coater, a knife coater, a bar coater, a slot die coater, an air knife coater, a reverse gravure coater, and a vario gravure coater, spray coating method, and an inkjet method.

The amount of the pressure-sensitive adhesive applied is within a range of preferably 1 to 50 μm, more preferably 10 to 40 μm, and most preferably 20 to 30 μm in terms of thickness, from the viewpoint that the moisture amount of the adhesive held is increased under the high-humidity environment to adversely affect the gas barrier properties of the gas barrier layer when the amount of the pressure-sensitive adhesive applied is thick, and the stress alleviating performance is degraded when the amount of the pressure-sensitive adhesive applied is thin.

Further, it is preferable to use an adhesive film in a state where a pressure-sensitive adhesive layer is interposed between two of upper and lower separator films, and in this case, pasting of an anti-reflection film can be conducted using tension and pressure as parameters.

The applied pressure is not particularly limited as long as a target adhesive force is obtainable, but is preferably 0.5 to 60 kgf/cm², and more preferably 1 to 50 kgf/cm² in terms of surface pressure. Heating may be performed as necessary without any particular limitation, but is preferably performed from normal temperature to a temperature equal to lower than Tg of a support of the anti-reflection film.

[Antistatic Layer]

The antistatic layer can be effectively used in order to provide the function of preventing the support from being charged when the resin film is handled. Specifically, static charge prevention can be achieved by providing an antistatic layer containing an ion conductive substance or the like. Herein, the ion conductive substance refers to a substance exhibiting electrical conductivity and containing ions that are carriers for electricity. For example, ionic polymers can be mentioned.

Examples of the ionic polymers may include anionic polymers as described in literatures such as JP 49-23828 B, B 49-23827 B, and JP 47-28937 B; ionene-type polymers having a dissociable group at the main chain as described in literatures such as JP 55-734 B, JP 50-54672 A, JP 59-14735 B, JP 57-18175 B, JP 57-18176 B, and JP 57-56059 B; and cationic pendant-type polymers having a cationic dissociable group at the side chain as described in literatures such as JP 53-13223 B, JP 57-15376 B, JP 53-45231 B, JP 55-145783 B, JP 55-65950 B, JP 55-67746 B, JP 57-11342 B, JP 57-19735 B, JP 58-56858 B, JP 61-27853 A, and JP 62-9346 B.

Examples of conductive substances may include ionene conductive polymers as described in JP 9-203810 A and quaternary ammonium cationic conductive polymer particles having intermolecular cross-linking.

Further, since a cross-linked cationic conductive polymer as a dispersed particulate polymer can maintain a cationic component in the particles with a high concentration and a high density, the cross-linked cationic conductive polymer has excellent conductivity and does not have deterioration in conductivity even under a low relative humidity.

Further, as the metal oxides that are conductive fine particles, ZnO, TiO₂, SnO₂, Al₂O₃, In₂O₃, SiO₂, MgO, BaO, MoO₂, V₂O₅ and the like, or complex oxides thereof are preferable, and particularly, ZnO, TiO₂, and SnO₂ are preferable. As for examples which have a heterogeneous atom, for example, it is effective to add ZnO with Al, In, or the like, TiO₂ with Nb, Ta, or the like, and SnO₂ with Sb, Nb, halogen element, or the like. The amount of such heterogeneous atoms added is preferably within a range of 0.01 to 25 mol % and particularly preferably within a range of 0.1 to 15 mol %.

Further, these conductive metal oxide powders have a volume resistivity of 107 Ωcm or less and particularly 105 Ωcm or less, and the conductive layer preferably contain powder, which has a specific structure having a primary particle size of 100 Å to 0.2 μm and a long diameter of the higher-order structure of 30 nm to 6 μm in 0.01 to 20% in terms of volume fraction.

Herein, as a resin used for maintaining the antistatic agent, for example, it is possible to use cellulose derivatives such as cellulose diacetate, cellulose triacetate, cellulose acetatebutylate, cellulose acetatephthalate, and cellulose nitrate; polyesters such as polyvinyl acetate, polystyrene, polycarbonate, polybutylene terephthalate, and copolybutylene tere/iso-phthalate; polyvinyl alcohol derivatives such as polyvinyl alcohol, polyvinylformal, polyvinylacetal, polyvinylbutyral, and polyvinylbenzal; norbornene-based polymers containing a norbornene compound; and acrylic resin such as polymethyl methacrylate, polyethyl methacrylate, polypropylthyl methacrylate, polybutyl methacrylate, and polymethyl acrylate or copolymers of acrylic resins and other resins, but the resin is not particularly limited thereto. Of them, cellulose derivatives or acrylic resins are preferable, and acrylic resins are most preferably used.

As a resin used in the resin layer such as an antistatic layer, the aforementioned thermoplastic resin having a weight average molecular weight of more than 400,000 and a glass transition temperature of 80 to 110° C. is preferable in terms of optical characteristics and surface quality of the coating layer.

The glass transition temperature can be obtained by the method described in JIS K 7121-2012. The resin used herein is preferably 60% by mass or more and further preferably 80% by mass or more of the entire resin used in the lower layer, and as necessary, an active ray curing resin or a thermosetting resin can also be added. These resins are applied as binders in a state of being dissolved in the aforementioned appropriate solvent.

In an application composition applied to form an antistatic layer, as solvents, hydrocarbons, alcohols, ketones, esters, glycolethers, and the like can be appropriately mixed and used, but the solvents are not particularly limited thereto.

Examples of the hydrocarbons include benzene, toluene, xylene, hexane, and cyclohexane. Examples of the alcohols include methanol, ethanol, n-propyl alcohol, isopropyl alcohol, n-butanol, 2-butanol, tert-butanol, pentanol, 2-methyl-2-butanol, and cyclohexanol. Examples of the ketones include acetone, methylethylketone, methylisobutylketone, and cyclohexanone. Examples of the esters include methyl formate, ethyl formate, methyl acetate, ethyl acetate, isopropyl acetate, amyl acetate, ethyl lactate, and methyl lactate. Examples of the glycolethers (C1 to C4) include methyl cellosolve, ethyl cellosolve, propyleneglycol monomethylether (PGME), propyleneglycol monoethylether, propyleneglycol mono-n-propylether, propyleneglycol monoisopropylether, and propyleneglycol monobutylether. Examples of the propyleneglycol mono (C1 to C4) alkyletheresters include propyleneglycol monomethyletheraceatate, and propyleneglycol monoethyletheracetate. Examples of other solvent include N-methylpyrrolidone. The application compositions are not particularly limited thereto, and solvent obtained by appropriately mixing these compositions are preferably used.

Examples of the method of applying the application composition in this technique include a doctor coating method, an extrusion coating method, a slide coating method, a roll coating method, a gravure coating method, a wire bar coating method, a reverse coating method, a curtain coating method, an extrusion coating method or an extrusion coating method with a hopper described in U.S. Pat. No. 2,681,294. By using appropriately these methods, the application can be performed such that the dry thickness is preferably 0.1 to 20 μm and more preferably 0.2 to 5 μm.

[Resin Base Material]

The resin base material used as the element substrate and the sealing substrate is not particularly limited as long as it is a flexible base material capable of providing flexibility to the organic EL element. As the flexible base material, a transparent resin film is exemplified. Herein, in the present invention, “being transparent” refers to “having a light transmittance of 60% or more at a wavelength of 550 nm, and particularly, the light transmittance is preferably 70% or more.

Examples of the resin film include polyesters such as polyethylene terephthalate (PET) and polyethylene naphthalate (PEN); polyethylene, polypropylene; cellulose esters or their derivatives such as cellophane, cellulose diacetate, cellulose triacetate (TAC), cellulose acetatebutylate, cellulose acetate propionate (CAP), cellulose acetatephthalate, and cellulose nitrate; polyvinylidene chloride, polyvinyl alcohol, polyethylene vinyl alcohol, syndiotactic polystyrene, polycarbonate, norbornene resin, polymethylpentene, polyether ketone, polyimide, polyether sulfone (PES), polyphenylene sulfide, polysulfones, polyetherimide, polyether ketone imide, polyamide, fluororesin, nylon, polymethyl methacrylate, acrylic resins or polyacrylates; and cycloolefin resins such as ARTON (trade name, manufactured by JSR Corporation) and APEL (trade name, manufactured by Mitsui Chemicals, Inc.

In the present invention, as the material of the resin base material, polyethylene terephthalate (PET) is preferable, and from the viewpoint of maintaining gas barrier properties at storage under high-temperature and high-humidity environment, a polyesters (PET) film having hydrolysis resistance is particularly preferable. As the PET film having hydrolysis resistance, commercially available flexible base materials such as Lumirror X10 (manufactured by Toray Industries, Inc.) and SHINEBEAM (manufactured by TOYOBO CO., LTD.) can be used.

[Gas Barrier Layer]

The gas barrier layer of this embodiment is provided on a base material when an organic EL element is formed in production of an organic EL panel and has a function of locking oxygen and moisture in the air. In the case of the organic EL element, permeation of oxygen and moisture causes the light emitting performance to be temporally degraded. For this reason, it is necessary to block the organic EL element from the outside world by sealing the organic EL element with the gas barrier layer or the sealing member. The gas barrier layer may be formed on at least one surface of the resin base material.

The gas barrier layer may be organic or inorganic. Further, the gas barrier layer may include both of at least one organic layer and at least one inorganic layer or may be formed by alternately laminating two or more organic layers and two or more inorganic layers. As a material of the inorganic layer, metal oxides of metals such as silicon, aluminum, and titanium, metal nitride, metal oxynitride, and the like are mentioned.

As for the inorganic gas barrier layer, a layer formed from a silicon-based compound is useful. In particular, by forming a thin film of silicon oxide, silicon nitride, or silicon oxynitride on a resin base material, it is possible to provide excellent gas barrier properties to the resin base material.

In order to form a thin film of silicon oxide, silicon nitride, or silicon oxynitride on a resin base material, in terms of production efficiency, a method is preferable in which a precursor, which generates silicon oxynitride, silicon nitride, or silicon oxynitride through reaction, is applied onto a resin base material, and the precursor is converted into silicon oxide, silicon nitride, or silicon oxynitride through reaction. Specific examples of the precursor, which is converted into silicon oxide, silicon nitride, or silicon oxynitride through reaction, may include polysiloxane having a Si—O—Si bond (including polysilsesquioxane), polysilazane having a Si—N—Si bond, and polysiloxazane having both a Si—O—Si bond and a Si—N—Si bond.

In order to form a thin film of silicon oxide, silicon nitride, or silicon oxynitride on a resin base material, in terms of production efficiency, a method is preferable in which a precursor, which generates silicon oxide, silicon nitride, or silicon oxynitride through reaction, is applied onto a resin base material, and the precursor is converted into silicon oxide, silicon nitride, or silicon oxynitride through reaction. Specific examples of the precursor, which is converted into silicon oxide, silicon nitride, or silicon oxynitride through reaction, may include polysiloxane having a Si—O—Si bond (including polysilsesquioxane), polysilazane having a Si—N—Si bond, and polysiloxazane having both a Si—O—Si bond and a Si—N—Si bond.

(Polysilazane Modified Layer)

The polysilazane modified layer is a layer provided for making the unevenness of the surface of the gas barrier layer, and a translucent layer formed on the gas barrier layer (not illustrated). The polysilazane modified layer is a layer formed by subjecting the coating film of the polysilazane-containing liquid to the modification treatment. The polysilazane modified layer is mainly formed of a silicon oxide or a silicon oxynitride compound.

A method for forming the polysilazane modified layer include a method for forming a layer containing a silicon oxide or a silicon oxynitride compound, by performing modification treatment after coating at least one coating liquid containing a polysilazane compound on a base material.

As to the supply of a silicon oxide or a silicon oxynitride compound for forming the polysilazane modified layer, the coating on the surface of the base material rather than the supply as gas like in a chemical vapor deposition (CVD) method makes it possible to form a more uniform and smooth layer. In the case of the CVD method and the like, it is known that unnecessary particles are generated in the gas phase, at the same time as the process of the vapor deposition of a raw material having an increased reactivity in the gas phase on the surface of the base material. As the result of the accumulation of these generated particles, the smoothness of the base material surface deteriorates. In the applying method, the suppression of the generation of these particles becomes possible by not allowing raw materials to exist in a gas-phase reaction space. Consequently, a polysilazane modified layer having a smooth surface can be formed through the use of the applying method.

By providing the polysilazane modified layer on the gas barrier layer, unevenness on the gas barrier layer surface is alleviated so that defects due to short-circuiting of the first electrode can be prevented and peeling-off of the first electrode and the organic functional layer can be prevented.

(1) Coating Film Containing Polysilazane

The coating film containing polysilazane is formed by applying a coating liquid containing a polysilazane compound at least in one layer on the base material.

Any appropriate method may be employed as a coating method. Specific examples thereof include a spin coating method, a roll coating method, a flow coating method, an inkjet method, a spray coating method, a printing method, a dip coating method, a casting film formation method, a bar coating method, and a gravure printing method. The thickness of the application may be set appropriately corresponding to an object. For example, the thickness of the application may be set so that the thickness after drying is preferably about 0.001 to 100 μm, further preferably about 0.01 to 10 μm, and most preferably about 0.01 to 1 μm.

“Polysilazane” is a polymer having a silicon-nitrogen bond and is a ceramic precursor inorganic polymer such as SiO₂, Si₃N₄, and an intermediate solid solution SiOxNy of both the substances, made of Si—N, Si—H, N—H, and the like. The polysilazane is represented by the following General Formula (I).

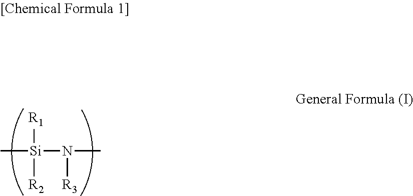

In General Formula (I), R₁, R_{2,} and R₃ each independently represent a hydrogen atom, an alkyl group, an alkenyl group, a cycloalkyl group, an aryl group, an alkylsilyl group, an alkylamino group, an alkoxy group, or the like.

From the viewpoint of denseness of a gas barrier layer to be obtained, perhydropolysilazane in which all of R₁, R₂, and R₃ are hydrogen atoms is particularly preferable.

Meanwhile, organopolysilazane in which a part of the hydrogen portion to be bonded to Si thereof is substituted by an alkyl group or the like has the advantage that the generation of crack is suppressed even when (an average) film thickness is made larger, since adhesiveness to the base material of the base is improved by having an alkyl group such as a methyl group and toughness can be provided to a ceramic film based on hard and brittle polysilazane. The perhydropolysilazane or organopolysilazane may be appropriately selected, or these can also be used in mixture, depending on use applications.

The perhydropolysilazane is presumed to have a structure in which a linear structure and a ring structure with 6- and 8-membered ring as the center exist. The molecular weight thereof is about 600 to 2000 (in terms of polystyrene) in number average molecular weight (Mn), and the perhydropolysilazane is a liquid or solid material and differs depending on the molecular weight. These are available in the market in a solution state dissolved in an organic solvent, and a commercially available product can be used as is, as a polysilazane-containing coating liquid.

In order to perform coating so as not to damage the film base material, one that is made into a ceramic at a comparatively low temperature and is modified into silica as described in JP 8-112879 A.

Other examples of polysilazane changing into ceramic at low temperatures include siliconalkoxide-added polysilazane obtained by causing polysilazane represented by the above General Formula (I) to react with siliconalkoxide (JP 5-238827 A), glycidol-added polysilazane obtained by causing the polysilazane to react with glycidol (JP 6-122852 A), alcohol-added polysilazane obtained by causing the polysilazane to react with alcohol (JP 6-240208 A), metal carboxylate-added polysilazane obtained by causing the polysilazane to react with metal carboxylate (JP 6-299118 A), acetylacetonate complex-added polysilazane obtained by causing the polysilazane to react with acetylacetonate complex containing a metal (JP 6-306329 A), and metal-fine-particle-added polysilazane obtained by causing the polysilazane to react with metal fine particles (JP 7-196986 A).

Specific examples of organic solvents that is used for preparing a liquid containing polysilazane include hydrocarbon solvents such as aliphatic hydrocarbon, alicyclic hydrocarbon, and aromatic hydrocarbon, halogenated hydrocarbon solvents, and ethers such as aliphatic ether and alicyclic ether. Specifically, there are hydrocarbons such as pentane, hexane, cyclohexane, toluene, xylene, Solvesso, and terpene, halogenated hydrocarbons such as methylene chloride and trichloroethane, ethers such as dibutyl ether, dioxane, and tetrahydrofuran, and the like. These solvents may be selected in accordance with an object such as the solubility of polysilazane, a vapor deposition rate of a solvent, or the like and a plurality of solvents may be mixed. Incidentally, an alcohol-based and water-containing solvent is not preferable because of reacting easily with polysilazane.

The concentration of polysilazane in the polysilazane-containing coating liquid is about 0.2 to 35% by mass, although the concentration differs depending on an intended silica layer thickness or a pot life of the coating liquid.

A catalyst of amine or metal can also be added in order to accelerate the conversion to a silicon oxide compound. Specific examples thereof include AQUAMICANAX120-20, NN110, NN310, NN320, NL110A, NL120A, NL150A, NP110, NP140, and SP140, all of which are manufactured by AZ ELECTRONIC MATERIALS.

(2) Moisture Removal Treatment with Respect to Coating Film

It is preferable to remove moisture from the coating film containing polysilazane before the modification treatment. As a method of removing moisture in the coating film, the process is preferably separated into a first process for the purpose of removing a solvent in the coating film and a subsequent second process for the purpose of removing moisture in the coating film.

In the first process, drying conditions for mainly removing a solvent can be appropriately determined by a method of thermal treatment or the like, and the conditions of removing the moisture at this time are also acceptable. A thermal treatment temperature is preferably high from the viewpoint of a rapid treatment, but temperature and treatment time are determined in consideration of a thermal damage to a resin base material. For example, in a case where a PET base material having a glass transition temperature (Tg) of 70° C. is used in the resin base material, the thermal treatment temperature can be set to 200° C. or lower. The treatment time is preferably set so that the solvent is to be removed, and in a short time so as to reduce a thermal damage to the resin base material. When the thermal treatment temperature is 200° C. or lower, the treatment time can be set within 30 minutes.

The second process is a process for removing moisture in the coating film, and an aspect of being maintained in a low humidity environment is preferable as a method for removing moisture. The humidity in the low humidity environment changes depending on temperatures, and thus, regarding the relation between temperature and humidity, a preferable aspect is shown on the basis of the specification of the dew-point temperature. A preferable dew-point temperature is 4 degrees or less (temperature 25 degrees/humidity 25%), a more preferable dew-point temperature is −8 degrees or less (temperature 25 degrees/humidity 10%), and a further preferable dew-point temperature −31 degrees or less (temperature 25 degrees/humidity 1%), and the time to be maintained changes appropriately depending on the thickness of the coating film. Under conditions in which the thickness of the coating film is 1 μm or less, a preferable dew-point temperature is −8 degrees or less and the time to be maintained is 5 minutes or longer. In addition, reduced-pressure drying may be performed so that the moisture is easily removed. The pressure in the reduced-pressure drying can be selected from a normal pressure to 0.1 MPa.

As the preferable conditions in the second process with respect to the conditions in the first process, for example, when the solvent is removed at a temperature of 60 to 150° C. for a treatment time of 1 to 30 minutes in the first process, conditions for removing the moisture in which a dew point of 4 degrees or less and a treatment time of 5 to 120 minutes can be selected in the second process. The classification of the first process and the second process can be distinguished on the basis of the change in the dew point, and the classification can be carried out by the change in the difference of dew points of process environments by 10 degrees or more.

The coating film is preferably subjected to modification treatment, after the removal of the moisture in the second process, while maintaining the state.

(3) Moisture Content of Coating Film

The moisture quantity of the coating film can be detected by the following analytical method.

### (Headspace Gas Chromatography/Mass Spectrometry)

Apparatus: HP6890GC/HP5973MSD

Oven: 40° C. (2 min), after that, temperature is raised to 150° C. at a rate of 10° C./min

Column: DB-624 (0.25 tumid×30 m)

Injection port: 230° C.

Detector: SIM m/z=18

HS condition: 190° C.·30 min

The moisture content in the coating film is defined as a value obtained by dividing the moisture quantity obtained by the above-described analytical method, by the volume of the coating film, and the moisture content is preferably 0.1% or less in a state where the moisture has been removed in the second process. The moisture content is further preferably 0.01% or less (detection limit or less).

(4) Modification Treatment

A known method based on the conversion reaction of polysilazane can be selected as the modification treatment. Heating treatment at 450° C. or higher is required for the production of a silicon oxide film or a silicon oxynitride film by a substitution reaction of a silazane compound, and adaptation is difficult in the case of flexible substrates such as plastic. For adaptation for a plastic substrate, it is preferable to use a method, such as plasma treatment, ozone treatment, or ultraviolet irradiation treatment, capable of a conversion reaction at lower temperatures.

(4-1) Plasma Treatment

A known method can be used for plasma treatment used for the modification treatment, and atmospheric pressure plasma treatment is preferable. In the case of the atmospheric pressure plasma treatment, nitrogen gas and/or atoms in Group 18 in the periodic table, specifically, helium, neon, argon, krypton, xenon, radon, or the like is used as a discharge gas. Among these, nitrogen, helium, and argon are preferably used, and in particular, nitrogen is low in cost, which is preferable.

As an example of the plasma treatment, the atmospheric pressure plasma treatment will be described. Specifically, the atmospheric pressure plasma is one, as described in WO 2007/026545 A, in which two or more electric fields of different frequencies are formed in a discharge space, and an electric field in which a first radio frequency electric field and a second radio frequency electric field are superposed is preferably formed.

In the atmospheric pressure plasma treatment, a frequency ω2 of the second radio frequency electric field is higher than a frequency col of the first radio frequency electric field, the relation among an intensity V₁ of the first radio frequency electric field, an intensity V₂ of the second radio frequency electric field, and an intensity V₃ of a discharge starting electric field satisfies

V₁≥V₃>V₂ or V₁>V₃≥V₂

and the output density of the second radio frequency electric field is 1 W/cm² or more.

For example, even in the case of discharge gas having a high discharge starting electric field intensity such as nitrogen gas, it is possible to start discharge, to maintain a plasma state with high density and stability, and to form a thin film of high performance, by adopting such discharge conditions.

According to the above measurement, in a case where nitrogen gas is set as a discharge gas, the discharge starting electric field intensity V₃ (1/2Vp-p) is about 3.7 kV/mm, and accordingly, in the above-described relation, it is possible to excite the nitrogen gas and to make the nitrogen gas into a plasma state, by applying a first applied electric field intensity as V₁≥3.7 kV/mm.

Herein, as the frequency of a first power source, 200 kHz or less can be preferably used. Further, as the waveform of the electric field, both a continuous wave and a pulse wave are usable. The lower limit is desirably about 1 kHz. Meanwhile, as the frequency of a second power source, 800 kHz or more can be preferably used. A higher frequency of the second power source gives a higher plasma density to thereby obtain a dense and high-quality thin film. The upper limit is desirably about 200 MHz.

The formation of radio frequency electric fields from such two power sources is necessary for starting discharge of a discharge gas having a high discharge starting electric field intensity by the first radio frequency electric field, and the plasma density can be made high and a dense and high-quality thin film can be formed by a high frequency and high output density of the second radio frequency electric field.

(4-2) Ultraviolet Irradiation Treatment

As a method for the modification treatment, treatment by ultraviolet irradiation is also preferable. Ozone and active oxygen atoms generated with ultraviolet rays (synonymous with ultraviolet light) have a high oxidization capability and can produce a silicon oxide film or silicon oxynitride film having high denseness and insulation properties at a low temperature.

Through this ultraviolet irradiation, the base material is heated, O₂ and H₂O contributing to ceramization (conversion into silica), an ultraviolet absorber, or polysilazane itself is excited and activated, so that polysilazane is excited, ceramization of polysilazane is accelerated, and a ceramic film to be obtained becomes denser. The ultraviolet irradiation is effective any time after the formation of the coating film.

In the present invention, any ultraviolet generator that is usually used can be used.

Incidentally, in the present example, the “ultraviolet rays” generally means electromagnetic waves having a wavelength of 10 to 400 nm, but in the case of the ultraviolet irradiation treatment other than the vacuum ultraviolet (10 to 200 nm) treatment described below, ultraviolet rays having a wavelength of 210 to 350 nm are preferably used.

For ultraviolet irradiation, irradiation intensity and irradiation time are set within the ranges of not damaging the base material which supports the coating film to be irradiated.

In a case where a plastic film is used as the base material, for example, irradiation can be carried out for 0.1 seconds to 10 minutes using a lamp of 2 kW (80 W/cm×25 cm) with a distance between the base material and the lamp set such that the strength of the base material surface is 20 to 300 mW/cm², preferably 50 to 200 mW/cm².

Generally, in a case where a plastic film or the like used as the base material, the base material may deform or the strength of the base material may decrease when the base material temperature during ultraviolet irradiation treatment becomes 150° C. or higher. However, in the case of a film of polyimide or the like, which has high heat resistance, or a base material of metal or the like, the treatment can be carried out at a higher temperature. Therefore, the base material temperature during ultraviolet irradiation does not have a general upper limit and can be appropriately set by a person skilled in the art according to the type of the base material. Further, the ultraviolet irradiation atmosphere is not particularly limited, and hence ultraviolet irradiation may be carried out in the air.

Examples of the method of generating such ultraviolet rays include a metal halide lamp, a high-pressure mercury lamp, a low-pressure mercury lamp, a xenon arc lamp, a carbon arc lamp, an excimer lamp (single wavelength of 172 nm, 222 nm, or 308 nm, manufactured by, for example, USHIO Inc.), and a UV light laser, but are not particularly limited thereto. Further, when the coating film irradiated with the generated ultraviolet rays, in order to achieve uniform irradiation and improve efficiency, it is desirable to apply the ultraviolet rays, which are from the light source, to the coating film after reflected by a reflecting plate.

The ultraviolet irradiation is applicable to either of batch treatment and continuous treatment, and appropriate selection can be made therefrom according to the shape of the coated base material. For example, in the case of batch treatment, the base material (for example, a silicon wafer or the like) having the coating film on the surface can be treated in an ultraviolet furnace provided with the ultraviolet light source as described above. The ultraviolet furnace itself is generally known, and for example, one manufactured by EYE GRAPHICS Co., Ltd. can be used. Further, in a case where the base material having the coating film on the surface is in the form of a long film, it can be ceramized by continuously being irradiated with ultraviolet rays in a drying zone provided with the ultraviolet light source as described above while carried. Time required for ultraviolet irradiation depends on the composition and concentration of the base material to be coated and the coating, but is generally 0.1 seconds to 10 minutes, preferably 0.5 seconds to 3 seconds.

(4-3) Vacuum Ultraviolet Irradiation Treatment; Excimer Irradiation Treatment

In the present invention, as a further preferable method for the modification treatment, treatment by vacuum ultraviolet irradiation is mentioned. The treatment by vacuum ultraviolet irradiation is a method of forming a silicon oxide film at a relatively low temperature by allowing an oxidization reaction with active oxygen or ozone to proceed while directly cutting the bond of atoms by action of only photons, which is called a photon process, using energy of light having a wavelength of 100 to 200 nm, which is greater than interatomic bonding force in a silazane compound, preferably using energy of light having a wavelength of 100 to 180 nm.

As a vacuum ultraviolet light source required for this method, a rare gas excimer lamp is preferably used.

Herein, a rare gas of Xe, Kr, Ar, Ne, or the like is called an inert gas since atoms thereof are not chemically bonded to form a molecule. However, atoms of a rare gas which gains energy through discharge or the like (excited atoms) can be bonded to other atoms to form a molecule. In a case where the rare gas is xenon,

e+Xe→e+Xe*

Xe*+Xe+Xe→Xe²*+Xe

and when Xe²*, which is an excited excimer molecule, makes a transition into the ground state, excimer light of 172 nm is emitted. Features of the excimer lamp are, for example, that efficiency is high since emission concentrates at one wavelength and almost no light other than necessary light is emitted.

Further, the temperature of a target can be kept low since unnecessary light is not emitted. Furthermore, instant lighting/flashing is available since little time is required for starting/restarting.

As a method for excimer light emission, a method using dielectric gas barrier discharge is known. The dielectric gas barrier discharge is very thin discharge similar to lightning, called micro discharge, which occurs in a gas space arranged between electrodes through a dielectric (transparent quartz in the case of the excimer lamp) by application of a high-frequency high voltage of several tens of kHz to the electrodes. When streamers of the micro discharge arrive at the tube wall (dielectric), charges are accumulated on the surface of the dielectric, so that the micro discharge disappears. Thus, the dielectric gas barrier discharge is discharge which is the micro discharge spreading over the entire tube wall and repeating occurrence and disappearance. Hence, flickering of light recognized by naked eyes occurs. Further, since the streamers of a very high temperature directly arrive at the tube wall locally, degradation of the tube wall may be accelerated.

As a method for efficient excimer light emission, besides the dielectric gas barrier discharge, electrodeless field discharge can also be used. It is electrodeless field discharge by capacitive bonding, alias RF discharge. The lamp and electrodes and arrangement thereof may be basically the same as those for the dielectric gas barrier discharge, but lighting is established by applying a high frequency of several MHz to between the electrodes. As described above, the electrodeless field discharge is discharge uniform in terms of space and time, and therefore a long-life lamp free from flickering is obtained.

In the case of the dielectric gas barrier discharge, the micro discharge occurs only between electrodes, and therefore for discharge in the entire discharge space, the outside electrode needs to be one which covers the entire outer surface and penetrates light to be extracted to the outside. Hence, an electrode with thin metallic wires formed into a meshwork is used. This electrode is liable to be damaged by ozone or the like generated by vacuum ultraviolet light especially in an oxygen atmosphere since the thinnest possible wires are used.

In order to prevent this, it is required that the periphery of the lamp, that is, the interior of the irradiation device, be brought into an atmosphere of an inert gas such as nitrogen, and a window of synthetic quartz be provided so that irradiation light can be extracted. The window of synthetic quartz is not only an expensive consumable article but also causes a loss of light.

A double cylindrical lamp has an outer diameter of about 25 mm, so that a difference between distances to the irradiation surface from immediately below the lamp shaft and from the lateral surface of the lamp cannot be ignored, and a large difference exists therebetween in intensity of illumination. Therefore, even if such lamps are arranged to closely contact with one another, a uniform illumination distribution cannot be obtained. The irradiation device provided with the window of synthetic quartz can make the distances in the oxygen atmosphere uniform, so that a uniform illumination distribution is obtained.

In a case where the electrodeless field discharge is used, an outer electrode does not need to be in the form of a meshwork. Glow discharge spreads over the entire discharge space merely with an outer electrode provided at a part of the outer surface of the lamp. As the outer electrode, an electrode made of an aluminum block and doubling as a light reflecting plate is usually used on the back surface of the lamp. However, since the outer diameter of the lamp is large as with the case of the dielectric gas barrier discharge, synthetic quartz is required for a uniform illumination distribution.

The most significant feature of a narrow-tube excimer lamp is a simple structure. That is, the quartz tube is merely filled with a gas for excimer light emission with the both ends thereof closed. Therefore, a very inexpensive light source can be provided.

Since the double cylindrical lamp is processed so that the ends of the inner and outer tubes are connected and closed, it is liable to be damaged during use or transportation as compared with the narrow-tube lamp. Further, the outer diameter of the tube of the narrow-tube lamp is about 6 to 12 mm. When the outer diameter thereof is too thick, a high voltage is required for starting.

As the form of discharge, either the dielectric gas barrier discharge or the electrodeless field discharge can be used. The electrode may have such a shape that a surface in contact with the lamp is flat. However, if this surface is made to fit the curved surface of the lamp, the lamp can be firmly fixed, and the electrode can closely contact the lamp, so that the discharge becomes more stable. Further, the curved surface, if formed into a mirror surface with aluminum, serves as a light reflecting plate.

An Xe excimer lamp emits ultraviolet rays having a short wavelength of 172 nm as a single wavelength and is therefore excellent in light emitting efficiency. The light has a large oxygen absorption coefficient, so that radical oxygen atom species or ozone can be generated in a high concentration with a very small amount of oxygen. Energy of light having a short wavelength of 172 nm, which causes the bond of organic substances to be dissociated, is known to have a high capability. Owing to the active oxygen or ozone and the high energy of ultraviolet radiations, modification of the coating film containing polysilazane can be achieved in a short period of time. This makes it possible, in contrast to a low-pressure mercury lamp which emits light having wavelengths of 185 nm and 254 nm and plasma cleaning, to shorten processing time associated with a high throughput, to reduce the area for equipment and to irradiate an organic material, a plastic substrate and the like, which are liable to be damaged by heat.

The excimer lamp has high light emitting efficiency and therefore can be lit by introduction of low power. Further, the excimer lamp has such a feature that increase in surface temperature of an irradiation target is prevented since it does not emit light of a long wavelength, which causes increase in temperature by light, but emits energy of a single wavelength in the ultraviolet range. Thus, the excimer lamp is suitable for materials of flexible films, such as PET, which are easily affected by heat.

(5) Smoothness: Surface Roughness Ra

A surface roughness (Ra) of the surface of the polysilazane modified layer is preferably 2 nm or less and further preferably 1 nm or less. As the result of the surface roughness being within the range, when the first electrode is provided on the gas barrier film, a light transmission efficiency is enhanced by a smooth film surface having a little unevenness and an energy conversion efficiency is enhanced by the reduction of a leak current between electrodes. The surface roughness (Ra) of the polysilazane modified layer can be measured by the following method.

The surface roughness is calculated from a cross-sectional curve of unevenness continuously measured using a detector having a sensing pin with a minimum tip radius by an atomic force microscope (AFM), for example, using DI3100 manufactured by Digital Instruments, is measured plural times within a zone of several tens μm in the measurement direction with a sensing pin having a minimum tip radius, and is a roughness related to the amplitude of fine unevenness.

[Undercoat Layer]

The undercoat layer is a layer formed by using a compound having a specific relation between nitrogen atom and silver (Ag) that is a main material constituting the metal layer, of compounds containing a nitrogen atom. Herein, the effective action energy ΔEef represented by the following Formula (1) is defined as the interaction energy between the compound and silver. Further, the undercoat layer is formed by using a compound having a specific relation in which this effective action energy ΔEef satisfies the following Formula (2).

ΔEef=n×ΔE/s Formula (1):

n: Number of nitrogen atom(s) (N) contained in compound and stably bonded with silver (Ag)

ΔF: Interaction energy between nitrogen atom (N) and silver (Ag)

s: Surface area of compound

−0.40≤ΔEef[kcal/mol·Å²]≤−0.10 Formula (2):

The number (n) of nitrogen atom(s) (N) contained in the compound and stably bonded with silver is the number obtained by selecting and counting, from the nitrogen atoms contained in the compound, only the nitrogen atom(s) stably bonded with silver as specific nitrogen atom(s). The nitrogen atoms from which the specific nitrogen atom(s) is (are) to be selected include all nitrogen atoms contained in the compound, instead of being limited to the nitrogen atom(s) which constitute the heterocycle. The selection of the specific nitrogen atom(s) from all nitrogen atoms contained in the compound is performed in the following manner either with a bond distance [r(Ag.N)] between silver and nitrogen atom in the compound calculated by, for example, a molecular orbital calculation method as an index, or with an angle between nitrogen atom and silver with respect to the ring containing nitrogen atom in the compound, that is, a dihedral angle [D] as an index. Incidentally, the molecular orbital calculation is performed, for example, by using Gaussian 03 (Gaussian, Inc., Wallingford, Conn., 2003).

First, in a case where the selection of the specific nitrogen atom(s) is performed with the bond distance [r(Ag.N)] as an index, considering the steric structure of each compound, the distance at which nitrogen atom(s) in the compound is stably bonded with silver is set as a “stable bond distance.” Further, the bond distance [r(Ag.N)] for each nitrogen atom contained in the compound is calculated by using the molecular orbital calculation method. The nitrogen atom(s) whose calculated bond distance [r(Ag.N)] is close to the “stable bond distance” is selected as the specific nitrogen atom(s). Such selection of the nitrogen atom(s) is applicable to a compound having many nitrogen atoms which constitute the heterocycle, and a compound having many nitrogen atoms which do not constitute the heterocycle.

Further, in a case where the selection of the specific nitrogen atom(s) is performed with the dihedral angle [D] as an index, the molecular orbital calculation method is used to calculate the dihedral angle [D]. The nitrogen atom(s) whose calculated dihedral angle [D] satisfies “D <10 degrees” is selected as the specific nitrogen atom(s). Such selection of the nitrogen atom(s) is applicable to a compound having many nitrogen atoms which constitute the heterocycle.

Further, the interaction energy [ΔE] between silver (Ag) and nitrogen (N) contained in the compound is a value calculated by the molecular orbital calculation method and is an interaction energy between nitrogen selected in the above manner and silver.

Furthermore, the surface area [s] is calculated with respect to the optimized structure by using Tencube/WM (manufactured by Tencube Co., Ltd.).

It is further preferable that the effective action energy ΔEef defined above falls in a range satisfying the following Formula (3).

ΔEef[kcal/mol·Å²]≤−0.20 Formula (3):

The compound containing a nitrogen atom that constitutes the undercoat layer is not particularly limited as long as it is a compound containing a nitrogen atom in the molecule, but a compound which has a heterocycle having a nitrogen atom as a hetero atom is preferable. Examples of the heterocycle having a nitrogen atom as a hetero atom include aziridine, azirine, azetidine, azete, azolidine, azole, piperidine, pyridine, azepane, azepine, imidazole, pyrazole, oxazole, thiazole, imidazoline, pyrazine, morpholine, thiazine, indole, isoindole, benzimidazole, purine, quinoline, isoquinoline, quinoxaline, cinnoline, pteridine, acridine, carbazole, benzo-C-cinnoline, porphyrin, chlorine, and choline.

Further, examples of a compound to be preferably used as the compound which has a heterocycle having a nitrogen atom as a hetero atom include a compound having a structure represented by General Formula (1) or General Formula (2) described in JP 2013-157089 A and a compound having a structure represented by General Formula (1) or General Formula (2) described in JP 2013-242988 A.

Incidentally, since the undercoat layer according to the present invention is sequentially produced from the lower side when the element substrate side is regarded as the lower side with respect to the organic functional layer, the undercoat layer has an arrangement illustrated in FIG. 1. However, depending on the production procedures, the undercoat layer may be provided on a surface opposite to the transparent electrode (between the gas barrier layer and the transparent electrode).

[Transparent Electrode]

As the transparent electrode (anode side), for example, a transparent oxide semiconductor having a work function suitable for hole injection is used. The transparent oxide semiconductor has a high transmittance. In order to lower the surface resistance per thickness, the thickness of the transparent electrode is preferably 10 to 200 nm. Examples of the transparent oxide semiconductor used in the transparent electrode include indium tin oxide (ITO), indium zinc oxide (IZO), and InGaO₃.

As the transparent electrode (cathode side), a small-thickness metal having a work function suitable for electron injection is used. In order to improve the optical transmittance, the thickness of the transparent electrode is preferably in a range of several nm to several tens of nm.

Examples of the small-thickness metal used in the transparent electrode include Ag, Al, Au, and Cu. In the case of using Ag, Al, or Cu, high electrical conductivity is achieved. In the case of using Au, the effect that the transparent electrode is less prone to oxidization is achieved.

In addition, platinum, rhodium, palladium, ruthenium, iridium, osminium, and the like may be used. These materials have good thermal properties and chemical properties, are less prone to oxidization even at a high temperature, and do not chemically react with a substrate material.

In addition, an alloy formed from a plurality of metal materials, such as MgAg or LiAl, may be used. Incidentally, the small-thickness metal forms a film, for example, by using a vacuum vapor deposition method or the like, but at this time, it is preferable to lower the surface resistance of the small-thickness metal by providing the undercoat layer as described above and to increase the transmittance.

Examples of a material suitable for this undercoat layer include organic materials which have a heterocycle having a nitrogen atom as a hetero atom. Further, by interposing the small-thickness metal with a transparent oxide semiconductor such as ITO, the transmittance can also be improved.

As the transparent electrode, a conductive resin which can be produced at low cost with an application method may be used. Examples of a conductive resin material used in the hole transport material include poly(3,4-ethylenedioxythiophene) (PEDOT)/poly(4-styrenesulfonate) (PSS), poly(3-hexylthiophene) (P3HT), poly(3-octylthiophene) (P3OT), poly(3-dodecylthiophene-2,5-diyl) (P3DDT), and a copolymer of fluorene and bithiophene (F8T2). In the case of PEDOT/PSS, an optical constant of visible light is (refractive index n=1.5 and extinction coefficient κ=0.01), and a reflectance of an electrode viewed from the light emitting layer has the same value as that of a resin having a refractive index of 1.5 and the reflectance is lower than that of PCBM.

[Configuration of Transparent Electrode]

The organic EL element used in the present invention includes a pair of transparent electrodes as an anode and a cathode, and at least one of the transparent electrodes is preferably a transparent electrode containing silver as a main component, which is described herein.

The transparent electrode is a very thin metal film such that the electrode exhibits light transmittance and plasmon loss does not occur at the surface irradiated with light. Further, the electrode layer is a very thin metal film such that the electrode layer has conductivity and is formed continuously. Specifically, the transparent electrode preferably has a light transmittance of 60% or more at a wavelength of 550 nm, a thickness of 1 to 10 nm, and a sheet resistance within a range of 0.0001 to 50 Ω/square, preferably 0.01 to 30 Ω/square.

In a case where such a transparent electrode is used as an anode of the organic EL element, the transparent electrode is formed by using a metal having a larger work function than that of the cathode.

On the other hand, in a case where the transparent electrode is used as a cathode of the organic EL element, the transparent electrode is formed by using a metal having a smaller work function than that of the anode. For example, in a case where the transparent electrode that forms an anode is formed from an oxide semiconductor such as ITO, as an example of a metal, which forms the electrode layer, as a cathode, silver or an alloy containing silver as a main component is mentioned. The transparent electrode using silver or an alloy containing silver as a main component is preferably laminated on the undercoat layer using a compound containing a nitrogen atom to be adjacent to the undercoat layer. For example, such a transparent electrode is laminated via the undercoat layer.

The transparent electrode is preferably formed to be adjacent to the undercoat layer formed by using an alloy containing silver as a main component. Examples of a method for forming such a transparent electrode include a method using a wet process such as an applying method, an inkjet method, a coating method, or a dipping method; and a method using a dry process such as a vapor deposition method (resist heating, EB method, or the like), a sputtering method, or a CVD method. Among them, a vapor deposition method is preferably applied. Further, although the transparent electrode exhibits sufficient conductivity without being annealed at a high temperature after the formation of the conductive layer by forming the transparent electrode on the undercoat layer, the transparent electrode may be subjected to annealing at a high temperature as necessary.

The metal forming such a transparent electrode is, for example, silver (Ag) or an alloy containing silver as a main component. The silver (Ag) may contain palladium (Pd), copper (Cu), gold (Au), or the like for ensuring the stability of silver, and the purity of silver is 99% or more. Further, content of silver in the alloy containing silver as a main component is 50% or more. Examples of such an alloy include silver magnesium (AgMg), silver copper (AgCu), silver palladium (AgPd), silver palladium copper (AgPdCu), silver indium (Agin), silver gold (AgAu), silver aluminum (AgAl), silver zinc (AgZn), silver tin (AgSn), silver platinum (AgPt), silver titanium (AgTi), and silver bismuth (AgBi).

Further, the transparent electrode may have a configuration in which a plurality of silver layers or a plurality of layers of the alloy containing silver as a main component are laminated as necessary. That is, the transparent electrode may have a configuration in which a plurality of silver layers and a plurality of alloy layers are alternately laminated or a configuration in which different types of alloy layers are laminated. Further, as an example of the transparent electrode having a two-layer configuration, a configuration in which a silver layer is laminated on the undercoat layer via an aluminum (Al) layer. The aluminum layer is not necessarily a continuous layer, but may be a layer having an island pattern or holes. In this case, a portion of the silver layer is provided to be adjacent to the undercoat layer. In this way, a configuration may be employed in which another metal is interposed between the undercoat layer and a film containing silver as a main component.

[Transparent Electrode Containing Thin Metal Wire and Transparent Conductive Member]

The transparent electrode containing a thin metal wire and a transparent conductive member can be produced by appropriately using the method described in WO 2012/053520 A.

(Metal Nanoparticle)

The thin metal wire preferably contains metal nanoparticles. Examples of the metal nanoparticles may include a simple metal selected from the metal element group consisting of gold, silver, copper, platinum, palladium, nickel, and aluminum, or an alloy composed of two or more metals selected from the metal element group consisting of gold, silver, copper, platinum, palladium, nickel, and aluminum.

The particle diameter of the metal nanoparticle is 1 nm or more and 100 nm or less, more preferably 50 nm or less, and still more preferably 30 nm or less.

The metal nanoparticles can be prepared by a conventional method, for example, by reducing a metal compound corresponding to the metal nanoparticle in a solvent in the presence of protective colloid and a reducing agent.

The metal compound corresponding to the metal nanoparticle may be, for example, metal oxides, metal hydroxides, metal sulfides, metal halides, metal acid salts [such as metal inorganic acid salts (sulfates, nitrates, oxo acid salts such as perchlorates, and the like) and metal organic acid salts (acetates and the like)]. Incidentally, the form of the metal salt may be any of a simple salt, a double salt, and a complex salt, and may be a polymeric form (for example, dimer) and the like. These metal compounds can be used alone or in combination of two or more kinds thereof. Among these metal compounds, metal halides, metal acid salts [such as metal inorganic acid salts (sulfates, nitrates, oxo acid salts such as perchlorates, and the like) and metal organic acid salts (acetates and the like)], and the like are used in many cases. Incidentally, these metal compounds may be used by being dissolved or dispersed in a solvent (for example, in the form of a solution of an aqueous solvent such as an aqueous solution).

[Configuration Example of Organic Functional Layer]

The typical examples of the configuration of portions (anode/organic functional layer/cathode) interposed between the element substrate and the sealing substrate of the organic EL element will be described.

(i) Anode/organic functional layer unit [first organic functional layer group (hole injection transport layer)/light emitting layer/second organic functional layer group (electron injection transport layer)]/cathode

(ii) Anode/organic functional layer unit [first organic functional layer group (hole injection transport layer)/light emitting layer/second organic functional layer group (hole blocking layer/electron injection transport layer)]/cathode

(iii) Anode/organic functional layer unit [first organic functional layer group (hole injection transport layer/electron blocking layer)/light emitting layer/second organic functional layer group (hole blocking layer/electron injection transport layer)]/cathode

(iv) Anode/organic functional layer unit [first organic functional layer group (hole injection layer/hole transport layer)/light emitting layer/second organic functional layer group (electron transport layer/electron injection layer)]/cathode

(v) Anode/organic functional layer unit [first organic functional layer group (hole injection layer/hole transport layer)/light emitting layer/second organic functional layer group (hole blocking layer/electron transport layer/electron injection layer)]/cathode

(vi) Anode/organic functional layer unit [first organic functional layer group (hole injection layer/hole transport layer/electron blocking layer)/light emitting layer/second organic functional layer group (hole blocking layer/electron transport layer/electron injection layer)]/cathode

Further, a non-emitting intermediate layer may be provided between the light emitting layers. The intermediate layer may be a charge generation layer and may have a multiphoton unit configuration.

Regarding the outline of the organic EL element applicable to the present invention, for example, configurations described in JP 2013-157634 A, JP 2013-168552 A, JP 2013-177361 A, JP 2013-187211 A, JP 2013-191644 A, JP 2013-191804 A, JP 2013-225678 A, JP 2013-235994 A, JP 2013-243234 A, JP 2013-243236 A, JP 2013-242366 A, JP 2013-243371 A, JP 2013-245179 A, JP 2014-003249 A, JP 2014-003299 A, JP 2014-013910 A, JP 2014-017493 A, JP 2014-017494 A, and the like can be mentioned.

Further, specific examples of a tandem type organic EL element include element configurations and constituent materials described in U.S. Pat. No. 6,337,492, U.S. Pat. No. 7,420,203, U.S. Pat. No. 7,473,923, U.S. Pat. No. 6,872,472, U.S. Pat. No. 6,107,734, U.S. Pat. No. 6,337,492, WO 2005/009087 A, JP 2006-228712 A, JP 2006-24791 A, JP 2006-49393 A, JP 2006-49394 A, JP 2006-49396 A, JP 2011-96679 A, JP 2005-340187 A, JP 4711424 A, JP 3496681 B2, JP 3884564 B2, JP 4213169 B2, JP 2010-192719 A, JP 2009-076929 A, JP 2008-078414 A, JP 2007-059848 A, JP 2003-272860 A, JP 2003-045676 A, WO 2005/094130, and the like, but the present invention is not limited thereto. In the following configuration description, for the purpose of convenience, only the configuration having one organic functional layer unit is illustrated, and the description of the lamination tandem configuration is omitted.

Further, respective layers that constitute the organic functional layer will be described.

[Light Emitting Layer]

In the light emitting layer that constitutes the organic EL element, a phosphorescence emitting compound or a fluorescent compound can be used as the light emitting material, but in the present invention, particularly, a configuration in which a phosphorescence emitting compound is contained as the light emitting material is preferable.

This light emitting layer is a layer which emits light through recombination of electrons injected from an electrode or an electron transport layer and holes injected from a hole transport layer. A portion that emits light may be either the inside of the light emitting layer or an interface between the light emitting layer and its adjacent layer.

The configuration of the light emitting layer is not particularly limited as long as the light emitting material contained therein satisfies a light emission requirement. In addition, there may be a plurality of light emitting layers having the same light emission spectrum and/or light emission maximum wavelength. In this case, it is preferable that a non-emitting intermediate layer is present between the respective light emitting layers.

The total thickness of the light emitting layers is preferably within a range of 1 to 100 nm, and from the viewpoint of obtaining a lower driving voltage, is further preferably within a range of 1 to 30 nm. Incidentally, the total thickness of the light emitting layers is a thickness including the thickness of the intermediate layer in a case where the non-emitting intermediate layer is present between the light emitting layers.

The light emitting layer as described above can be formed by subjecting a light emitting material or a host compound described below to any of known methods such as a vacuum vapor deposition method, a spin coating method, a casting method, a Langmuir Blodgett (LB) method, and an inkjet method.

Further, the light emitting layer may also include a mixture of a plurality of light emitting materials. A mixture of a phosphorescence emitting material and a fluorescence emitting material (also referred to as a fluorescent dopant or a fluorescent compound) may also be used in the same light emitting layer. As the configuration of the light emitting layer, the light emitting layer includes a host compound (also referred to as a light emitting host or the like) and a light emitting material (also referred to as a light emitting dopant compound), in which light is preferably emitted from the light emitting material.

<Host Compound>

The host compound contained in the light emitting layer is preferably a compound having a phosphorescence quantum yield in phosphorescence emission of less than 0.1 at room temperature (25° C.). In addition, the host compound preferably has a phosphorescence quantum yield of less than 0.01. Further, among the compounds contained in the light emitting layer, a volume ratio in the layer is preferably 50% or more.

A known host compound may be used as the host compound, alone or in combination of a plurality of kinds. The use of a plurality of host compounds makes it possible to adjust transfer of charges, and to increase an efficiency of the organic EL element. Further, the use of a plurality of light emitting materials described below makes it possible to mix different light emissions, and to thereby obtain any desired emission color.

The host compound used in the light emitting layer may be a conventionally known low molecular weight compound, a conventionally known polymer compound having a repeating unit(s), or a conventionally known low molecular weight compound having a polymerizable group such as a vinyl group or an epoxy group (vapor deposition-polymerizable light emitting host).

Examples of the host compound suitable for use in the present invention may include compounds described in JP 2001-257076 A, JP 2001-357977 A, JP 2002-8860 A, JP 2002-43056 A, JP 2002-105445 A, JP 2002-352957 A, JP 2002-231453 A, JP 2002-234888 A, JP 2002-260861 A, JP 2002-305083 A, US 2005/0,112,407 A, US 2009/0,030,202 A, WO 2001/039234 A, WO 2008/056746 A, WO 2005/089025 A, WO 2007/063754 A, WO 2005/030900 A, WO 2009/086028 A, WO 2012/023947 A, JP 2007-254297 A, and EP 2034538 B.

<Light Emitting Material>

The light emitting material that can be used in the present invention includes a phosphorescence emitting compound (also referred to as a phosphorescent compound, a phosphorescence emitting material, or a phosphorescence emitting dopant) and a fluorescence emitting compound (also referred to as a fluorescent compound or a fluorescence emitting material). Particularly, it is preferable to use a phosphorescence emitting compound from the viewpoint that high light emitting efficiency can be obtained.

<Phosphorescence Emitting Compound>

The phosphorescence emitting compound is such a compound that light emission from an excited triplet state can be observed, and specifically, a compound that emits phosphorescence at room temperature (25° C.) and has a phosphorescence quantum yield at 25° C. of 0.01 or more. The phosphorescence quantum yield is preferably 0.1 or more.

The above-described phosphorescence quantum yield can be measured by a method described on p. 398 of Bunko II of Dai 4 Han Jikken Kagaku Koza 7 (Spectroscopy II of Lecture of Experimental Chemistry vol. 7, 4th edition) (1992, published by Maruzen Co., Ltd.). The phosphorescence quantum yield in a solution can be measured by using various solvents, and when the phosphorescence emitting compound used in the present invention, it is sufficient that the above-described phosphorescence quantum yield is 0.01 or more in any of arbitrary solvents.

The phosphorescence emitting compound can be appropriately selected and used from known compounds used in light emitting layers of general organic EL elements. The phosphorescence emitting compound is preferably a complex-based compound containing a metal belonging to Groups 8 to 10 in the element periodic table, and is more preferably an iridium compound, an osmium compound, a platinum compound (a platinum complex-based compound) or a rare earth complex. Of them, an iridium compound is most preferable.

In the present invention, at least one light emitting layer may contain two or more kinds of phosphorescence emitting compounds, and a ratio of concentration of the phosphorescence emitting compound in the light emitting layer may vary in the thickness direction of the light emitting layer.

Specific examples of known phosphorescence emitting compound that can be used in the present invention may include compounds described in the following literatures:

Nature, 395, 151 (1998), Appl. Phys. Lett., 78, 1622 (2001), Adv. Mater., 19, 739 (2007), Chem. Mater., 17, 3532 (2005), Adv. Mater., 17, 1059 (2005), WO 2009/100991 A, WO 2008/101842 A, WO 2003/040257 A, US 2006/835,469 A, US 2006/0,202,194 A, US 2007/0,087,321 A, and US 2005/0,244,673 A.

Further, examples may also include compounds described in Inorg. Chem., 40, 1704 (2001), Chem. Mater., 16, 2480 (2004), Adv. Mater., 16, 2003 (2004), Angew. Chem. lnt. Ed., 2006, 45, 7800, Appl. Phys. Lett., 86, 153505 (2005), Chem. Lett., 34, 592 (2005), Chem. Commun., 2906 (2005), Inorg. Chem., 42, 1248 (2003), WO 2009/050290 A, WO 2009/000673 A, U.S. Pat. No. 7,332,232, US 2009/0,039,776 A, U.S. Pat. No. 6,687,266, US 2006/0,008,670 A, US 2008/0,015,355 A, U.S. Pat. No. 7,396,598, US 2003/0138657 A, and U.S. Pat. No. 7,090,928.

Further, examples may also include compounds described in Angew. Chem. lnt. Ed., 47, 1 (2008), Chem. Mater., 18, 5119 (2006), Inorg. Chem., 46, 4308 (2007), Organometallics, 23, 3745 (2004), Appl. Phys. Lett., 74, 1361 (1999), WO 2006/056418 A, WO 2005/123873 A, WO 2006/082742 A, US 2005/0,260,441 A, U.S. Pat. No. 7,534,505, US 2007/0,190,359 A, U.S. Pat. No. 7,338,722, U.S. Pat. No. 7,279,704, and US 2006/103,874 A.

Furthermore, examples may also include compounds described in WO 2005/076380 A, WO 2008/140115 A, WO 2011/134013 A, WO 2010/086089 A, WO 2012/020327 A, WO 2011/051404 A, WO 2011/073149 A, JP 2009-114086 A, JP 2003-81988 A, and JP 2002-363552 A.

In the present invention, the phosphorescence emitting compound is preferably an organometallic complex having Ir as a central metal. The phosphorescence emitting compound is more preferably a complex having at least one coordination moiety from a metal-carbon bond, a metal-nitrogen bond, a metal-oxygen bond, and a metal-sulfur bond.

The above-described phosphorescence emitting compounds (also referred to as phosphorescence emitting metal complexes) can be synthesized by employing methods described in literatures such as Org. Lett., vol. 3, No. 16, pp. 2579 to 2581 (2001), Inorg. Chem., vol. 30, No. 8, pp. 1685 to 1687 (1991), J. Am. Chem. Soc., vol. 123, p. 4304 (2001), Inorg. Chem., vol. 40, No. 7, pp. 1704 to 1711 (2001), Inorg. Chem., vol. 41, No. 12, pp. 3055 to 3066 (2002), New J. Chem., vol. 26, p. 1171 (2002), Eur. J. Org. Chem., vol. 4, pp. 695 to 709 (2004), and reference literatures described in these literatures.

<Fluorescence Emitting Compound>

Examples of a fluorescence emitting compound include a coumarin-based coloring matter, a pyran-based coloring matter, a cyanine-based coloring matter, a croconium-based coloring matter, a squarylium-based coloring matter, an oxobenzanthracene-based coloring matter, a fluorescein-based coloring matter, a rhodamine-based coloring matter, a pyrylium-based coloring matter, a perylene-based coloring matter, a stilbene-based coloring matter, a polythiophene-based coloring matter, and a rare earth complex-based fluorescent material.

[Organic Functional Layer Group]

Next, as the organic functional layer group, respective layers included in the organic functional layer other than the light emitting layer will be described in order of a charge injection layer, a hole transport layer, an electron transport layer, and a blocking layer.

(Charge Injection Layer)

The charge injection layer is a layer provided between the electrode and the light emitting layer so as to reduce the drive voltage or improve the emission luminance. Such a layer is described in detail in “Organic EL Element and Forefront of Their Industrialization (published by NTS Inc., Nov. 30, 1998)” Part 2, Chapter 2, “Electrode Materials,” (pp. 123 to 166). Examples thereof include a hole injection layer and an electron injection layer.

A charge injection layer as a hole injection layer is generally provided between an anode and a light emitting layer or a hole transport layer, and a charge injection layer as an electron injection layer is generally provided between a cathode and a light emitting layer or an electron transport layer. In the present invention, the charge injection layer is characterized by being placed adjacent to the transparent electrode. Further, in a case where the charge injection layer is used for an intermediate electrode, it is sufficient that at least one of an electron injection layer and a hole injection layer adjacent to the intermediate electrode satisfies the requirements of the present invention.

The hole injection layer is a layer placed adjacent to the anode as a transparent electrode so as to reduce the drive voltage or improve the emission luminance. Such a layer is described in detail in “Organic EL Element and Forefront of Their Industrialization (published by NTS Inc., Nov. 30, 1998)” Part 2, Chapter 2, “Electrode Materials,” (pp. 123 to 166).

The hole injection layer is also described in detail in publications such as JP 9-45479 A, JP 9-260062 A, and JP 8-288069 A. Examples of materials used in the hole injection layer include porphyrin derivatives, phthalocyanine derivatives, oxazole derivatives, oxadiazole derivatives, triazole derivatives, imidazole derivatives, pyrazoline derivatives, pyrazolone derivatives, phenylenediamine derivatives, hydrazone derivatives, stilbene derivatives, polyarylalkane derivatives, triarylamine derivatives, carbazole derivatives, indolocarbazole derivatives, isoindole derivatives, acene derivatives such as anthracene and naphthalene derivatives, fluorene derivatives, fluorenone derivatives, polyvinyl carbazole, polymers or oligomers having aromatic amine incorporated in the main or side chain, polysilane, and conductive polymers or oligomers (such as polyethylenedioxythiophene (PEDOT):polystyrenesulfonic acid (PSS), aniline copolymers, polyaniline, and polythiophene).

Examples of the triarylamine derivatives include benzidine derivatives such as a-NPD (4,4′-bis[N-(1-naphthyl)-N-phenylamino]biphenyl), starburst derivatives such as MTDATA (4,4′,4″-tris[N-(3-methylphenyl)-N-phenylamino]triphenylamine), and compounds having a fluorene or anthracene moiety combined with the triarylamine core.

Further, hexaazatriphenylene derivatives such as those described in JP 2003-519432 A and JP 2006-135145 A can also be used as hole transport materials.

The electron injection layer is a layer provided between the cathode and the light emitting layer so as to reduce the drive voltage or improve the emission luminance. In a case where the cathode includes a transparent electrode according to the present invention, the electron injection layer is provided adjacent to the transparent electrode. The electron injection layer is described in detail in “Organic EL Element and Forefront of Their Industrialization (published by NTS Inc., Nov. 30, 1998)” Part 2, Chapter 2, “Electrode Materials,” (pp. 123 to 166).

The electron injection layer is also described in detail in publications such as JP 6-325871 A, JP 9-17574 A, and JP 10-74586 A. Specific examples of materials preferably used in the electron injection layer include metals such as strontium and aluminum, alkali metal compounds such as lithium fluoride, sodium fluoride, and potassium fluoride, alkali metal halide layers such as magnesium fluoride and calcium fluoride, alkaline earth metal compound layers such as magnesium fluoride, metal oxides such as molybdenum oxide and aluminum oxide, and metal complexes such as lithium 8-hydroxyquinolate (Liq). Further, in the present invention, in a case where the transparent electrode is the cathode, it is particularly preferable to use organic materials such as metal complexes. The electron injection layer is desirably a very thin film, which preferably has a thickness in the range of 1 nm to 10 μm although it depends on the constituent material.

(Hole Transport Layer)

The hole transport layer includes a hole transport material having the function of transporting holes. In abroad sense, a hole injection layer and an electron blocking layer also have the function of the hole transport layer. The hole transport layer may be a single layer or a multilayer structure.

The hole transport material has one of the ability to inject or transport holes and the ability to block electrons. The hole transport material may be any of organic and inorganic materials. Examples thereof include triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, silazane derivatives, aniline copolymers, conductive high-molecular oligomers, and thiophene oligomers.

The hole transport material may be any of the above materials, and a porphyrin compound, an aromatic tertiary amine compound, and a styrylamine compound can be used. An aromatic tertiary amine compound is particularly preferably used.

Typical examples of the aromatic tertiary amine compound and the styrylamine compound include N,N,N′,N′-tetraphenyl-4,4′-diaminophenyl, N,N′-diphenyl-N,N′-bis(3-methylphenyl)-[1,1′-biphenyl]-4,4′-diamine (abbreviated as TPD), 2,2-bis(4-di-p-tolylaminophenyl)propane, 1,1-bis(4-di-p-tolylaminophenyl)cyclohexane, N,N,N′,N′-tetra-p-tolyl-4,4′-diaminobiphenyl, 1,1-bis(4-di-p-tolylaminophenyl)-4-phenylcyclohexane, bis(4-dimethylamino-2-methylphenyl)phenylmethane, bis(4-di-p-tolylaminophenyl)phenylmethane, N,N′-diphenyl-N,N′-di(4-methoxyphenyl)-4,4′-diaminobiphenyl, N,N,N′,N′-tetraphenyl-4,4′-diaminodiphenyl ether, 4,4′-bis(diphenylamino)quadriphenyl, N,N,N-tri(p-tolyl)amine, 4-(di-p-tolylamino)-4′-[4-(di-p-tolylamino)styryl]stilbene, 4-N,N-diphenylamino-(2-diphenylvinyl)benzene, 3-methoxy-4′-N,N-diphenylaminostilbenzene, and N-phenylcarbazole.

The hole transport layer can be formed by subjecting any of the above hole transport materials to a known thin film forming method such as a vacuum vapor deposition method, a spin coating method, a casting method, a printing method including an inkjet method, or a Langmuir Blodgett (LB) method. The thickness of the hole transport layer is not particularly preferable, but is typically about 5 nm to 5 μm and preferably in a range of 5 to 200 nm. The hole transport layer may be a single layer structure including one or two or more of the above materials.

Further, the material for the hole transport layer can also be doped with an impurity for increasing the p-type conductivity. Examples of such an impurity include those described in JP 4-297076 A, JP 2000-196140 A, JP 2001-102175 A, J. Appl. Phys., 95, 5773 (2004), and the like.

As described above, the increase in the p-type conductivity of the hole transport layer makes it possible to form an element with lower power consumption, which is preferable.

(Electron Transport Layer)

The electron transport layer includes a material having the function of transporting electrons. In a broad sense, an electron injection layer and a hole blocking layer fall within the category of the electron transport layer. The electron transport layer may be formed as a single layer structure or a multilayer structure.

In the electron transport layer of a single layer structure or a multilayer structure, the electron transport material (also serving as a hole blocking material) constituting the layer part adjacent to the light emitting layer only needs to have the function of transmitting electrons to the light emitting layer when the electrons are injected from the cathode. The material with such properties can be any material selected from conventionally known compounds. Examples thereof include nitro-substituted fluoren derivatives, diphenylquinone derivatives, thiopyran dioxide derivatives, carbodiimide, fluorenylidenemethane derivatives, anthraquinodimethane, anthrone derivatives, and oxadiazole derivatives. Further, materials that can be used for the electron transport layer also include derived from the oxadiazole derivatives by replacing the oxygen atom in the oxadiazole ring with a sulfur atom; and quinoxaline derivatives having a quinoxaline ring known as an electron-withdrawing group. Furthermore, polymer materials having any of these materials incorporated in the polymer chain or polymer materials whose main chain is formed using any of these materials can also be used.

Further, materials that can be used for the electron transport layer also include 8-quinolinol derivative metal complexes such as tris(8-quinolinol)aluminum (abbreviated as Alq3), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, and bis(8-quinolinol)zinc (abbreviated as Znq), and metal complexes derived from any of these metal complexes by replacing the central metal with In, Mg, Cu, Ca, Sn, Ga, or Pb.

The electron transport layer can be formed by subjecting any of the above materials to a known thin film forming method such as a vacuum vapor deposition method, a spin coating method, a casting method, a printing method including an inkjet method, or an LB method. The thickness of the electron transport layer is not particularly limited, but is typically about 5 nm to 5 μm and preferably within a range of 5 to 200 nm. The electron transport layer may be a single layer structure including one or two or more of the above materials.

(Blocking Layer)

Examples of the blocking layer include a hole blocking layer and an electron blocking layer, and the blocking layer is a layer that is provided, as necessary, in addition to each constituting layer described above of the organic functional layer unit 3. For example, hole blocking layers and the like described in JP 11-204258 A, JP 11-204359 A, “Organic EL Element and Forefront of Their Industrialization (published by NTS Inc., Nov. 30, 1998)” (p. 237), and the like can be mentioned.

In a broad sense, the hole blocking layer has the function of an electron transport layer. The hole blocking layer includes a hole blocking material having the function of transporting electrons and a very low ability to transport holes so that it can increase the probability of recombination of electrons and holes by transporting electrons and blocking holes. Further, as necessary, the configuration of the electron transport layer can be used as the hole blocking layer. The hole blocking layer is preferably provided to be adjacent to the light emitting layer.

Meanwhile, in a broad sense, the electron blocking layer has the function of a hole transport layer. The electron blocking layer includes a material having the function of transporting holes and a very low ability to transport electrons so that it can increase the probability of recombination of electrons and holes by transporting holes and blocking electrons. Further, as necessary, the configuration of the hole transport layer can be used as the electron blocking layer. The thickness of the hole blocking layer applicable to the present invention is preferably in a range of 3 to 100 nm and more preferably in a range of 5 to 30 nm.

[Sealing Substrate]

A sealing means used for sealing the organic EL element can be, for example, a method of bonding a flexible sealing substrate to the cathode and the transparent substrate with an adhesive for sealing.

A sealing member may be placed to cover the display region of the organic EL element. The sealing member may be concave sheet-shaped or flat sheet-shaped. Further, there is no limitation on transparency and electrical insulating properties of the sealing member.

Specifically, a thin glass plate, a polymer plate, a film, a metal film (metal foil), and the like having flexibility are exemplified. As the glass plate, particularly, soda-lime glass, barium/strontium-containing glass, lead glass, aluminosilicate glass, borosilicate glass, barium borosilicate glass, quartz, and the like can be exemplified. Further, as the polymer plate, polycarbonate, acryl, polyethylene terephthalate, polyether sulfide, polysulfone, and the like can be exemplified. As the metal film, at least one metal selected from the group consisting of stainless steel, iron, copper, aluminum, magnesium, nickel, zinc, chromium, titanium, molybdenum, silicon, germanium, and tantalum, and alloys thereof are exemplified.

In the present invention, a polymer film and a metal film can be preferably used as the sealing substrate from the viewpoint that the thickness of the organic EL element can be decreased. Further, the polymer film preferably has a water-vapor permeability of 1×10⁻³ g/m²·24 h or less at a temperature of 25±0.5° C. and a relative humidity of 90±2% as measured by the method in conformity with JIS K 7129-1992, and more preferably has an oxygen permeability of 1×10⁻³ ml/m²·24h·atm (1 atm is 1.01325×10⁵ Pa) or less as measured by the method in conformity with JIS K 7126-1987 and a water-vapor permeability of 1×10⁻³ g/m²·24 h or less at a temperature of 25±0.5° C. and a relative humidity of 90±2%.

An inert gas such as nitrogen or argon (gas phase) or an inert liquid such as fluorinated hydrocarbon or silicone oil (liquid phase) can be injected into the gap between the sealing substrate and the display region (light emitting region) of the organic EL element. Further, the gap between the sealing substrate and the display region of the organic EL element can also be evacuated to vacuum, or a moisture absorbing compound can also be sealed in the gap.

Further, a sealing film can also be formed on the transparent substrate while the organic functional layer in the organic EL element is completely covered with the sealing film and the terminal parts of the anode as the first electrode and the cathode as the second electrode in the organic EL element are exposed.

Such a sealing film is formed by using an inorganic material or an organic material, and particularly, a material having the function of suppressing permeation of moisture, oxygen, or the like, for example, inorganic materials such as silicon oxide, silicon dioxide, and silicon nitride are used. Further, in order to improve brittleness of the sealing film, the sealing film may have a laminate structure using a film formed from organic materials together with a film formed from these inorganic materials.

A method for forming these sealing films is not particularly limited, and for example, it is possible to use a vacuum vapor deposition method, a sputtering method, a reactive sputtering method, a molecular beam epitaxial method, a cluster ion beam method, an ion plating method, a plasma polymerization method, an atmospheric pressure plasma polymerization method, a plasma CVD method, a laser CVD method, a thermal CVD method, a coating method, or the like.

The sealing film as described above is provided while the terminal parts of the anode as the first electrode and the cathode as the second electrode in the organic EL element are exposed and at least the light emitting functional layer is covered with the sealing film.

[Method for Producing Organic EL Element]

As a method for the organic EL element, an anode, a first organic functional layer group, a light emitting layer, a second organic functional layer group, and a cathode are laminated on a transparent base material to form a laminate.

First, a transparent base material is prepared, on which a thin film of a desired electrode material, for example, an anode material is deposited with a thickness of 1 μm or less, preferably a thickness in a range of 10 to 200 nm by a method such as vapor deposition or sputtering to form an anode. At the same time, a connection electrode part which is connected to an external power source is formed at an end of the anode.

Subsequently, a hole injection layer and a hole transport layer that constitute the first organic functional layer group, a light emitting layer, an electron transport layer that constitutes the second organic functional layer group, and the like are laminated on the anode in this order.

Each of these layers may be formed by a spin coating method, a casting method, an inkjet method, a vapor deposition method, a printing method, or the like. From the viewpoint of ease of uniform layer formation, low probability of pin-hole formation, and the like, a vacuum vapor deposition method or a spin coating method is particularly preferable. Further, the method used to form the layer may differ from layer to layer. In a case where a vapor deposition method is used to form these respective layers, the deposition conditions, although varying with the type of the compound used and other factors, are preferably selected as appropriate from the following common ranges: a boat heating temperature of 50 to 450° C., the degree of vacuum of 1×10⁻⁶ to 1×10⁻² Pa, a deposition rate of 0.01 to 50 nm/sec, a substrate temperature of −50 to 300° C., and a layer thickness of 0.1 to 5 μm.

After the second organic functional layer group is formed as described above, a cathode is formed on the top of the second organic functional layer group by any appropriate formation method such as a vapor deposition method or a sputtering method. At this time, the cathode is formed and patterned to have a terminal part extending from the top of the organic functional layer group to the edge of the transparent substrate, while it is insulated from the anode by the organic functional layer group.

After the cathode is formed, the transparent base material, the anode, the organic functional layer group, the light emitting layer, and the cathode are sealed with a sealing member. That is, a sealing member is provided on the transparent base material to cover at least the organic functional layer group while the terminal parts of the anode and cathode are exposed.

### EXAMPLES

Hereinafter, the present invention will be described in detail by means of Examples, but the present invention is not limited thereto. Incidentally, the term “parts” or “%” is used as “parts by mass” or “% by mass” unless particularly described otherwise in Examples.

[Production of Flexible Substrate Having Gas Barrier Layer]

A flexible substrate having a gas barrier layer produced herein (hereinafter, referred to as the substrate) can be used in any of an element substrate and a sealing substrate. Compounds used in the following Examples are described.

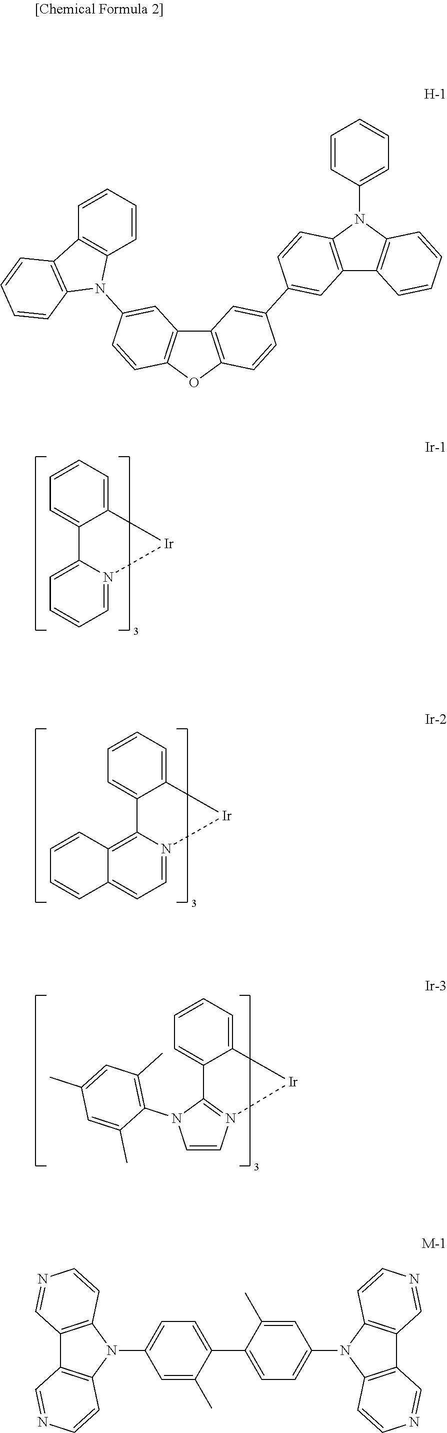

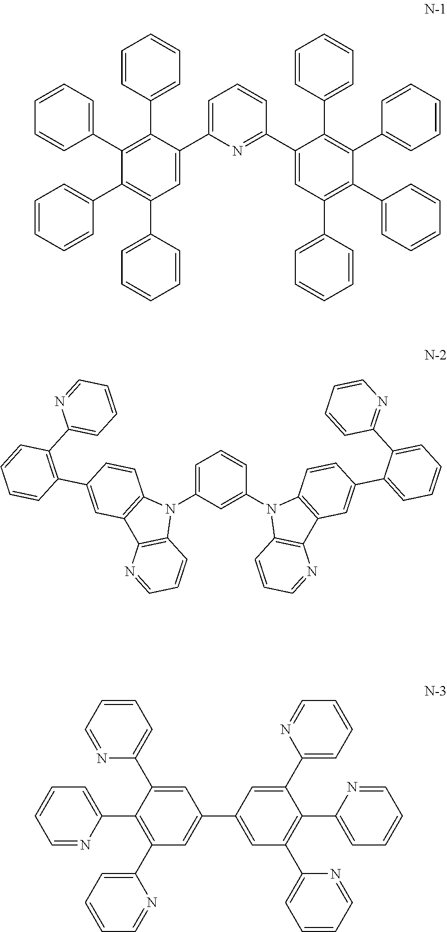 [SMILES: c1ccc(-c2cc(-c3cccc(-c4cc(-c5ccccc5)c(-c5ccccc5)c(-c5ccccc5)c4-c4ccccc4)n3)c(-c3ccccc3)c(-c3ccccc3)c2-c2ccccc2)cc1 ; c1ccc(-c2ccccc2-c2ccc3c(c2)c2ncccc2n3-c2cccc(-n3c4ccc(-c5ccccc5-c5ccccn5)cc4c4ncccc43)c2)nc1 ; c1ccc(-c2cc(-c3cc(-c4ccccn4)c(-c4ccccn4)c(-c4ccccn4)c3)cc(-c3ccccn3)c2-c2ccccn2)nc1]

<Production of Substrate 1>

A silicon nitride film was formed on a transparent resin base material attached with a double-sided hard coat layer (intermediate layer) (polyethylene terephthalate (PET) film attached with a clear hard coat layer (CHC) manufactured by KIMOTO Co., Ltd., the hard coat layer formed from a UV curing resin containing an acrylic resin as a main component, thickness of PET: 125 μm) under the following conditions.

In the formation of the silicon nitride film, a plasma CVD film formation apparatus, which includes an electrode provided to face a base material, a high-frequency power source supplying plasma excitation power to the electrode, a bias power source supplying bias power to a holding member holding the base material, and a gas supplying means for supplying a carrier gas or a raw material gas to the electrode, was used.

As a film forming gas, silane gas (SiH₄), ammonia gas (NH₃), nitrogen gas (N₂), and hydrogen gas (H₂) were used. The amounts of these gases supplied were set as follows: the silane gas: 100 sccm, the ammonia gas: 200 sccm, the nitrogen gas: 500 sccm, and the hydrogen gas: 500 sccm. Further, a film-forming pressure was set to 50 Pa.

To the electrode, 3000 W of plasma excitation power was supplied from the high-frequency power source at a frequency of 13.5 MHz. Further, to the holding member, 500 W of bias power was supplied from the bias power source. According to the above method, a substrate 1 having a silicon nitride film (gas barrier layer) with a thickness of 300 nm was produced. Incidentally, an antistatic layer containing an ionic polymer is formed on the surface at the side that is a light emitting surface of the substrate 1.

<Production of Substrate 2>

A gas barrier layer having a polysilazane-modified gas barrier layer was formed on a transparent resin base material attached with a double-sided hard coat layer (intermediate layer) (polyethylene terephthalate (PET) film attached with a clear hard coat layer (CHC) manufactured by KIMOTO Co., Ltd., the hard coat layer formed from a UV curing resin containing an acrylic resin as a main component, thickness of PET: 125 μm) under the following conditions.

Gas Barrier Layer 1

(Preparation of Polysilazane-Containing Coating Liquid)

A dibutyl ether solution containing 20% by mass of non-catalysis perhydropolysilazane (NN120-20 manufactured by AZ ELECTRONIC MATERIALS) and a dibutyl ether solution of 20% by mass perhydropolysilazane containing an amine catalyst (NAX120-20 manufactured by AZ ELECTRONIC MATERIALS) were mixed at a ratio of 4:1, and the resultant mixture was further diluted and adjusted with a dibutyl ether solvent such that a solid content of coating liquid became 5% by mass.

(Formation of Coating Film)

A gas barrier layer 1 (thickness: 110 nm) was formed on a base material by a slot die coater and was subjected to heating treatment at 80° C. to form a polysilazane coating film.

After the polysilazane coating film was formed, a gas barrier film was produced according to the method described below by irradiation of vacuum-ultraviolet light (excimer irradiation apparatus MODEL: MECL-M-1-200 manufactured by M. D. COM. Inc., wavelength: 172 nm, stage temperature: 100° C., cumulative light quantity: 3000 mJ/cm², oxygen concentration: 0.1%). A gas barrier layer 2 described below was laminated on the gas barrier layer 1.

Gas Barrier Layer 2

[Formation of Gas Barrier Layer by Plasma CVD Apparatus]

A silicon oxide gas barrier layer 2 (thickness: 270 nm) was formed on a support under the following film formation conditions by using an atmospheric pressure plasma film formation apparatus (a roll-to-roll type atmospheric pressure plasma CVD apparatus described in FIG. 1 of JP 2008-56967 A) according to an atmospheric pressure plasma method.

(Mixed Gas Composition)

Discharge gas: nitrogen gas 94.9% by volume

Thin film forming gas: tetraethoxysilane 0.1% by volume

Added gas: oxygen gas 5.0% by volume

(Film Formation Conditions)

<First Electrode Side>

Type of power source: PHF-6k, 100 kHz (continuous mode), manufactured by HAIDEN LABORATORY, Co., Ltd.

Frequency: 100 kHz

Output density: 10 W/cm²

Electrode temperature: 130° C.

<Second Electrode Side>

Type of power source: CF-5000-13M, 13.56 MHz, manufactured by Pearl Corporation

Frequency: 13.56 MHz

Output density: 10 W/cm²

Electrode temperature: 100° C.

The barrier layer 2 formed according to the above-described method was formed by silicon oxide (SiOC) and had a thickness of 270 nm, and an elastic modulus El was 30 GPa uniformly in the thickness direction.

Gas Barrier Layer 3

A gas barrier layer 3 was formed on the gas barrier layer 2 in such a manner that the gas barrier layer 2 (thickness: 270 nm) was formed by using the same coating liquid composition as in the gas barrier layer 1 and changing the solid content from 5% by mass to 10% by mass so as to have a cumulative light quantity of 6500 mJ/cm².

Gas Barrier Layer 4

Further, a gas barrier layer 4 was formed on the gas barrier layer 3 to have the same thickness and the same cumulative light quantity as those of the gas barrier layer 3.

Gas Barrier Layer 5

Further, a gas barrier layer 5 was formed on the gas barrier layer 4 to have the same thickness and the same cumulative light quantity as those of the gas barrier layer 3.

According to the above method, a substrate 2 having one silicon nitride film (gas barrier layer) and four polysilazane-modified gas barrier layers was produced. Incidentally, an antistatic layer containing an ionic polymer is provided on the surface at the light emission surface side of the substrate 2.

[Production of Organic Electroluminescent Element]

<Production of Organic EL Element 1>

The substrate 1 was used as the element substrate. On the surface, on which the gas barrier layer was formed, of the substrate 1, a film having a thickness of 120 nm was formed as an anode (one of transparent electrodes), using ITO followed by patterning to a support substrate. Thereafter, the transparent support substrate attached with this ITO transparent electrode was subjected to ultrasonic washing with isopropyl alcohol, drying in a dry nitrogen gas, and UV ozone washing for 5 minutes. Then, this transparent support substrate was fixed to a substrate holder in a plasma treatment chamber of a commercially available vacuum deposition device. Further, the constituent materials for the respective layers were each put in a crucible for deposition in the vacuum deposition device in an amount adequate for preparing each element. The used crucibles for deposition were each made of a material for resistive heating, namely, tungsten or molybdenum.

After the plasma treatment was performed for 2 minutes at an oxygen pressure of 1 Pa and an electric power of 100 W (electrode area: about 450 cm²), the substrate was transferred to an organic layer deposition chamber without the substrate being exposed to air, thereby forming an organic functional layer.

First, the vacuum deposition device was depressurized to the degree of vacuum of 1×10⁻⁴ Pa, and the crucible for deposition in which m-MTDATA was put was electrified to be heated so as to form a hole injection layer having a thickness of 10 nm at a deposition rate of 0.1 nm/sec on the transparent support substrate. Subsequently, α-NPD was deposited similarly to form a hole transport layer having a thickness of 30 nm. Next, each light emitting layer was formed according to the following procedure.

Ir-1, Ir-2, and a host compound H-1 were co-deposited at a deposition rate of 0.1 nm/sec such that the concentration of Ir-1 became 15% by mass and the concentration of Ir-2 became 2% by mass, thereby forming a green/red phosphorescence emitting layer having a light emission maximum wavelength of 622 nm and a thickness of 8 nm.

Subsequently, Ir-3 and the host compound H-1 were co-deposited at a deposition rate of 0.1 nm/sec such that the concentration of Ir-3 became 12% by mass, thereby forming a blue phosphorescence emitting layer having a light emission maximum wavelength of 471 nm and a thickness of 15 nm. Herein, the concentration of Ir-3 in the blue phosphorescence emitting layer is uniform from the anode in the thickness direction of the cathode.

Thereafter, M-1 was deposited to have a thickness of 5 nm, thereby forming a hole blocking layer. Further, CsF and M-1 were co-deposited to have a thickness ratio of 10%, thereby forming an electron transport layer having a thickness of 45 nm.

Subsequently, a heating boat containing potassium fluoride as an electron injecting material was electrically heated to form an electron injection layer on the electron transport layer. At this time, the deposition rate was set to 0.01 to 0.02 nm/sec and the thickness was set to 2 nm.

According to the above method, the organic functional layer was formed on the anode.

Subsequently, the element substrate on the organic functional layer was formed was transferred from the deposition chamber of the vacuum deposition device into a treatment chamber of a sputtering device attached with a target of an electrode material (aluminum (Al)) serving as a cathode while the vacuum state thereof was maintained. Then, a cathode (the other transparent electrode) having a thickness of 7 nm and using aluminum (Al) was formed at a film-forming rate of 0.3 to 5 nm/sec in the treatment chamber.

Next, a silicon nitride film was formed on the cathode under the following condition to form a gas barrier layer.

In the formation of the silicon nitride film, a plasma CVD film formation apparatus, which includes an electrode provided to face a base material, a high-frequency power source supplying plasma excitation power to the electrode, a bias power source supplying bias power to a holding member holding the base material, and a gas supplying means for supplying a carrier gas or a raw material gas to the electrode, was used.

As a film forming gas, silane gas (SiH₄), ammonia gas (NH₃), nitrogen gas (N₂), and hydrogen gas (H₂) were used. The amounts of these gases supplied were set as follows: the silane gas: 100 sccm, the ammonia gas: 200 sccm, the nitrogen gas: 500 sccm, and the hydrogen gas: 500 sccm. Further, a film-forming pressure was set to 50 Pa.

To the electrode, 3000 W of plasma excitation power was supplied from the high-frequency power source at a frequency of 13.5 MHz. Further, to the holding member, 500 W of bias power was supplied from the bias power source. According to the above method, a silicon nitride film (gas barrier layer) having a thickness of 300 nm was formed.

Subsequently, the substrate 1 was used as the sealing substrate, and a thermosetting adhesive was uniformly applied onto the surface of the gas barrier layer of the sealing substrate by using a dispenser to have a thickness of 20 μm. Then, lamination was performed on the element having the silicon nitride film formed thereon by using a commercially available roll lamination apparatus, and then thermal curing was performed.

As for the thermosetting adhesive, bisphenol A diglycidylether (DGEBA), dicyandiamide (DICY), and an epoxy-adduct-based curing promoter were used as an epoxy-based adhesive. As described above, the organic EL element 1 was produced.

<Production of Organic EL Element 2>

A UV curing epoxy-based resin was applied onto the gas barrier film element substrate of the organic EL element 1 to have a thickness of 4 μm, a laminate application type AR film (trade name: Lumiclear, manufactured by Toray Industries, Inc.) (hereinafter, also referred to as the AR film (type 1)) was pasted thereto, and the UV curing resin was cured by irradiation of ultraviolet rays using a high-pressure mercury lamp. According to this, an organic EL element 2 was produced.

<Production of Organic EL Element 3>

A UV curing epoxy-based resin was applied onto the sealing substrate of the organic EL element 2 to have a thickness of 4 μm, a laminate application type AR film (trade name: Lumiclear, manufactured by Toray Industries, Inc.) was pasted thereto, and the UV curing resin was cured by irradiation of ultraviolet rays using a high-pressure mercury lamp. According to this, an organic EL element 3 was produced.

<Production of Organic EL Element 4>

A laminate application type AR film (trade name: Lumiclear, manufactured by Toray Industries, Inc.) was pasted onto the element substrate of the organic EL element 1 by using SANCUARY DK manufactured by Sun A. Kaken Co., Ltd. (thickness: 25 μm) as a pressure-sensitive adhesive layer. According to this, an organic EL element 4 was produced.

The adhesive force was measured according to the following conditions.

The measurement was conducted according to the method in conformity with peeling-off at 90° of JIS Z0237 by using a combination of the following devices manufactured by IMADA.

Gauge; ZP-50N

Slad table; P90-200N

Stand; MX2-500N

The adhesive force at this time was 25 N/25 mm.

<Production of Organic EL Element 5>

An organic EL element 5 was produced in the same manner as in the organic EL element 4, and a laminate application type AR film (trade name: Lumiclear, manufactured by Toray Industries, Inc.) was further pasted onto the sealing substrate of the organic EL element 4 by using SANCUARY DK manufactured by Sun A. Kaken Co., Ltd. (thickness: 25 μm) as a pressure-sensitive adhesive layer. According to this, an organic electroluminescent element 5 was produced.

<Production of Organic EL Element 6>

In the production of the organic EL element 5, the heating boat containing the nitrogen-containing compound N-1 was electrified to be heated to form an undercoat layer as a cathode (the other transparent electrode) on the organic functional layer instead of the film formation of aluminum (Al). At this time, the thickness of the undercoat layer was set to 30 nm.

Incidentally, the effective action energy ΔEef between the nitrogen-containing compound N-1 and silver was −0.057 [kcal/mol·Å²].

Subsequently, the heating boat containing silver was electrified to be heated. According to this, a cathode (the other transparent electrode) having a thickness of 7 nm and using silver (Ag) was formed at a deposition rate of 0.3 nm/sec.

As described above, an organic EL element 6 was produced.

<Production of Organic EL Element 7>

An organic EL element 7 was produced in the same manner as in the production of the organic EL element 6, except that PANACLEAN PD-Sl (thickness: 25 μm) manufactured by PANAC Corporation was used as a pressure-sensitive adhesive layer instead of SANCUARY DK (thickness: 25 μm) manufactured by Sun A. Kaken Co., Ltd.

The adhesive force at this time was 5.4 N/25 mm.

<Production of Organic EL Element 8>

An organic EL element 8 was produced in the same manner as in the production of the organic EL element 6, except that the thickness of SANCUARY DK manufactured by Sun A. Kaken Co., Ltd. as a pressure-sensitive adhesive layer was changed from 25 μm to 15 μm.

The adhesive force at this time was 15 N/25 mm.

<Production of Organic EL Element 9>

An organic EL element 9 was produced in the same manner as in the production of the organic EL element 8, except that the substrate 2 was used in each of the element substrate and the sealing substrate instead of the substrate 1.

Then, a laminate application type AR film (trade name: Lumiclear, manufactured by Toray Industries, Inc.) was pasted as each pressure-sensitive adhesive layer on the surfaces of the element substrate and the sealing substrate by using a double-sided pressure-sensitive adhesive tape (trade name: HJ-9150W, manufactured by Nitto Denko Corporation). As described above, the organic EL element 9 was produced.

<Production of Organic EL Element 10>

An organic EL element 10 was produced in the same manner as in the production of the organic EL element 8, except that the heating boat containing the nitrogen-containing compound N-1 was electrified to be heated to form an undercoat layer (thickness: 30 nm) as an anode (one of transparent electrodes) on the element substrate instead of formation of ITO and the heating boat containing silver was electrified to be heated to form an anode (one of transparent electrodes) using silver (Ag) (thickness: 7 nm) at a deposition rate of 0.3 nm/sec.

<Production of Organic EL Element 11>

An organic EL element 11 was produced in the same manner as in the production of the organic EL element 10, except that the undercoat layers of the anode and the cathode respectively were formed by using a nitrogen-containing compound N-2 instead of the nitrogen-containing compound N-1.

Incidentally, the effective action energy ΔEef between the nitrogen-containing compound N-2 and silver was −0.230 [kcal/mol·Å²].

<Production of Organic EL Element 12>

An organic EL element 12 was produced in the same manner as in the organic EL element 11, except that the laminate application type AR film (trade name: Lumiclear, manufactured by Toray Industries, Inc.) was not used, and an AR film having a moth-eye structure (trade name: MOSMITE™, manufactured by Mitsubishi Rayon Co., Ltd.) (hereinafter, also referred to as the AR film (type 2)) was pasted to the surface of each of the gas barrier film element substrate and the gas barrier film sealing substrate by using a double-sided pressure-sensitive adhesive tape (trade name: HJ-9150W, manufactured by Nitto Denko Corporation) as a pressure-sensitive adhesive layer.

<Production of Organic EL Element 13>

An organic EL element 13 was produced in the same manner as in the production of the organic EL element 12, except that the undercoat layers of the anode and the cathode respectively were formed by using a nitrogen-containing compound N-3 instead of the nitrogen-containing compound N-2.

Incidentally, the effective action energy ΔEef between the nitrogen-containing compound N-2 and silver was -0.362 [kcal/mol·Å²]

<Production of Organic EL Element 14>

In the production of the organic EL element 11, instead of the formation of ITO, a thin metal wire pattern was printed as an anode (one of transparent electrodes) on the element substrate by a screen printing method with a silver nanoparticle ink 1 (TEC-PA-010; manufactured by InkTec Co., Ltd.) and a compact thick-film semi-automatic printing machine STF-150IP (manufactured by Tokai Shoji Co., Ltd.). The printing was conducted through a screen printing pattern of a square lattice having a width of 50 μm and a pitch of 1 mm such that the height of the thin wire after annealing became 1 μm. After printing, thermal treatment was conducted on a hot plate at 120° C. for 30 minutes to form a thin metal wire pattern.

A transparent conductive layer coating liquid having the following composition was pattern-applied by an inkjet printer onto the element substrate having the thin metal wire pattern obtained above to have a wet thickness of 10 μm. The support applied with the pattern was dried using a circulation thermostatic bath at 90° C. for 1 minute and then calcined at 230° C. for 2 minutes using an electric furnace, thereby forming a transparent conductive member.

[Composition of Transparent Conductive Layer Coating Liquid]

Conductive polymer dispersion liquid (Clevios TH510; manufactured by H. C. Starck GmbH, solid content: 1.7% by mass) 17.6 g

Aqueous solution of 20% by mass poly(2-hydroxyethyl acrylate) (viscosity: 2.4 cp; vibration viscometer) 3.5 g

Dimethyl sulfoxide 1.0 g

As described above, the anode (one of transparent electrodes) formed from the thin metal wire and the transparent conductive member was formed on the gas barrier film element substrate to produce an organic EL element 14.

<Production of Organic EL Element 15>

An organic EL element 15 was produced in the same manner as in the production of the organic EL element 14, except that the laminate application type AR film (trade name: Lumiclear, manufactured by Toray Industries, Inc.) was not used, and an AR film having a moth-eye structure (trade name: MOSMITE™, manufactured by Mitsubishi Rayon Co., Ltd.) was pasted to the surface of each of the gas barrier film element substrate and the gas barrier film sealing substrate by using a double-sided pressure-sensitive adhesive tape (trade name: HJ-9150W, manufactured by Nitto Denko Corporation) as a pressure-sensitive adhesive layer.

<Production of Organic EL Element 16>

An organic EL element 16 was produced in the same manner as in the production of the organic EL element 15, except that the nitrogen-containing compound N-3 was used instead of the nitrogen-containing compound N-2 in the cathode undercoat layer.

TABLE 1

| | Element substrate | | | | | | | |
|---|---|---|---|---|---|---|---|---|
| | | | Adhesive force | | Anode undercoat layer | | | Cathode undercoat layer |
| | AR film | | of pressure- | | Nitrogen- | | | Nitrogen- |
| Element | | Attachment | sensitive adhesive | | containing | ΔEef [kcal/ | | containing |
| No. | Type | method | [N/25 mm] | Type | compound | mol · Å²] | Anode | compound |
| 1 | None | — | — | 1 | — | — | ITO | — |
| 2 | 1 | UV curing resin | — | 1 | — | — | ITO | — |
| 3 | 1 | UV curing resin | — | 1 | — | — | ITO | — |
| 4 | 1 | Pressure-sensitive | 25 | 1 | — | — | ITO | — |
| | | adhesive | | | | | | |
| 5 | 1 | Pressure-sensitive | 25 | 1 | — | — | ITO | — |
| | | adhesive | | | | | | |
| 6 | 1 | Pressure-sensitive | 25 | 1 | — | — | ITO | n-1 |
| | | adhesive | | | | | | |
| 7 | 1 | Pressure-sensitive | 5.4 | 1 | — | — | ITO | n-1 |
| | | adhesive | | | | | | |
| 8 | 1 | Pressure-sensitive | 15 | 1 | — | — | ITO | n-1 |
| | | adhesive | | | | | | |
| 9 | 1 | Pressure-sensitive | 15 | 2 | — | — | ITO | n-1 |
| | | adhesive | | | | | | |
| 10 | 1 | Pressure-sensitive | 15 | 2 | N-1 | −0.057 | Ag | n-1 |
| | | adhesive | | | | | | |
| 11 | 1 | Pressure-sensitive | 15 | 2 | N-2 | −0.230 | Ag | n-2 |
| | | adhesive | | | | | | |
| 12 | 2 | Pressure-sensitive | 15 | 2 | N-2 | −0.230 | Ag | n-2 |
| | | adhesive | | | | | | |
| 13 | 2 | Pressure-sensitive | 15 | 2 | N-3 | −0.362 | Ag | n-3 |
| | | adhesive | | | | | | |
| 14 | 1 | Pressure-sensitive | 15 | 2 | N-2 | −0.230 | ※1 | n-2 |
| | | adhesive | | | | | | |
| 15 | 2 | Pressure-sensitive | 15 | 2 | N-2 | −0.230 | ※1 | n-2 |
| | | adhesive | | | | | | |
| 16 | 2 | Pressure-sensitive | 15 | 2 | N-3 | −0.362 | ※1 | n-3 |
| | | adhesive | | | | | | |

| | | | Sealing substrate | | | | |
|---|---|---|---|---|---|---|---|
| | | | | | | Adhesive force | |
| | Cathode undercoat layer | | | AR film | | of pressure- | |
| Element | ΔEef [kcal/ | | | | Attachment | sensitive adhesive | |
| No. | mol · Å²] | Cathode | Type | Type | method | [N/25 mm] | Remark |
| 1 | — | Al | 1 | None | — | — | Comparative |
| | | | | | | | Example |
| 2 | — | Al | 1 | None | — | — | Comparative |
| | | | | | | | Example |
| 3 | — | Al | 1 | 1 | UV curing resin | — | Comparative |
| | | | | | | | Example |
| 4 | — | Al | 1 | None | — | — | Present |
| | | | | | | | invention |
| 5 | — | Al | 1 | 1 | Pressure-sensitive | 25 | Present |
| | | | | | adhesive | | invention |
| 6 | −0.057 | Ag | 1 | 1 | Pressure-sensitive | 25 | Present |
| | | | | | adhesive | | invention |
| 7 | −0.057 | Ag | 1 | 1 | Pressure-sensitive | 5.4 | Present |
| | | | | | adhesive | | invention |
| 8 | −0.057 | Ag | 1 | 1 | Pressure-sensitive | 15 | Present |
| | | | | | adhesive | | invention |
| 9 | −0.057 | Ag | 2 | 1 | Pressure-sensitive | 15 | Present |
| | | | | | adhesive | | invention |
| 10 | −0.057 | Ag | 2 | 1 | Pressure-sensitive | 15 | Present |
| | | | | | adhesive | | invention |
| 11 | −0.230 | Ag | 2 | 1 | Pressure-sensitive | 15 | Present |
| | | | | | adhesive | | invention |
| 12 | −0.230 | Ag | 2 | 2 | Pressure-sensitive | 15 | Present |
| | | | | | adhesive | | invention |
| 13 | −0.362 | Ag | 2 | 2 | Pressure-sensitive | 15 | Present |
| | | | | | adhesive | | invention |
| 14 | −0.230 | Ag | 2 | 1 | Pressure-sensitive | 15 | Present |
| | | | | | adhesive | | invention |
| 15 | −0.230 | Ag | 2 | 2 | Pressure-sensitive | 15 | Present |
| | | | | | adhesive | | invention |
| 16 | −0.362 | Ag | 2 | 2 | Pressure-sensitive | 15 | Present |
| | | | | | adhesive | | invention |

※1: Thin metal wire + transparent conductive member

The following evaluations were conducted to the organic EL elements 1 to 16 produced as described above. The results thereof are presented in Table 2.

1. Evaluation of Each Element Immediately after Production

[Power Efficiency]

Front brightness of each element was measured by using a spectroradiometer CS-1000 (manufactured by Konica Minolta, Inc.) to determine power efficiency at a front brightness of 1000 cd/m². Incidentally, in Table 2, description was made in terms of relative values when the power efficiency of the organic EL element 1 was regarded as 100. The larger value indicates that power efficiency is excellent.

[Light Transmittance of Organic EL Element]

The light transmittance of each organic EL element was measured. In the measurement of the light transmittance, the light transmittance at a wavelength of 550 nm [% at 550 nm] using, as the baseline, the same base material as the sample was obtained using a spectrophotometer (U-3300 manufactured by Hitachi Co., Ltd.). The measurement result was presented as a relative value when the light transmittance of the organic EL element 1 was regarded as 100.

Incidentally, it was confirmed that the light transmittance at a wavelength of 550 nm of each of organic EL elements 4 to 16 of the present invention produced in the present examples was 70% or more.

2. Bending Resistance Test Evaluation of Each Organic EL Element

The bending resistance test in which each organic EL element was wound around a cylinder having a diameter of 10 cm with the sealing substrate side of each organic EL element facing inward, then held for 10 seconds, and made flat again, was performed 500 times. Thereafter, the following respective measurements were performed.

[Voltage Increase of Organic EL Element]

The driving voltage of each element at the time when the brightnesses reached 1000 cd before and after the bending test was measured. In the measurement of the driving voltage, front brightness on the element substrate side of each organic EL element and front brightness on the sealing substrate side of each organic EL element were measured and the voltage at the time when the sum of the both front brightnesses was 1000 cd/m² was regarded as the driving voltage. The brightnesses was measured by using a spectroradiometer CS-1000 (manufactured by Konica Minolta, Inc.). For each element, the measurement result was presented as a fluctuation range (%) with respect to the driving voltage before the bending resistance test. The smaller fluctuation range indicates that bending resistance is excellent.

[Light Transmittance of Organic EL Element]

The light transmittance of each element was measured. In the measurement of the light transmittance, the light transmittance at a wavelength of 550 nm [% at 550 nm] using, as the baseline, the same base material as the sample was obtained using a spectrophotometer (U-3300 manufactured by Hitachi Co., Ltd.). For each element, the measurement result was presented as a fluctuation range (%) with respect to the light transmittance before the bending resistance test. The smaller fluctuation range indicates that bending resistance is excellent.

3. High-Temperature Resistance Test Evaluation of Each Organic EL Element

Each element was wound around a cylinder having a diameter of 10 cm with the sealing substrate side of each element facing inward, and then held for 500 hours without any change under the environment at 85° C./20% RH. Thereafter, the following respective measurements were performed.

[Voltage Increase of Organic EL Element]

The driving voltage of each element at the time when the brightnesses reached 1000 cd before and after the bending test was measured. In the measurement of the driving voltage, front brightness on the element substrate side of each organic electroluminescent element and front brightness on the sealing member 1 substrate side of each organic electroluminescent element were measured and the voltage at the time when the sum of the both front brightnesses was 1000 cd/m² was regarded as the driving voltage. The brightnesses was measured by using a spectroradiometer CS-1000 (manufactured by Konica Minolta, Inc.). For each element, the measurement result was presented as a fluctuation range (%) with respect to the driving voltage before the high-temperature resistance test. The smaller fluctuation range indicates that high-temperature resistance is excellent.

[Light Transmittance of Organic EL Element]

The light transmittance of each element was measured. In the measurement of the light transmittance, the light transmittance at a wavelength of 550 nm [% at 550 nm] using, as the baseline, the same base material as the sample was obtained using a spectrophotometer (U-3300 manufactured by Hitachi Co., Ltd.). For each element, the measurement result was presented as a fluctuation range (%) with respect to the light transmittance before the high-temperature resistance test. The smaller fluctuation range indicates that high-temperature resistance is excellent.

TABLE 2

| | Evaluation immediately | | Bending resistance | | High-temperature resistance | | |
|---|---|---|---|---|---|---|---|
| | after production | | evaluation | | test evaluation | | |
| | Power | Light | Voltage | Light | Voltage | Light | |
| | efficiency | transmittance | increase | transmittance | increase | transmittance | |
| Element | (relative | (relative | (fluctuation | (fluctuation | (fluctuation | (fluctuation | |
| No. | value) | value) | range %) | range %) | range %) | range %) | Remark |
| 1 | 100 | 100 | 5 | 1 | 4 | 2 | Comparative |
| | | | | | | | Example |
| 2 | 101 | 103 | 5 | 8 | 5 | 9 | Comparative |
| | | | | | | | Example |
| 3 | 102 | 105 | 5 | 10 | 4 | 10 | Comparative |
| | | | | | | | Example |
| 4 | 101 | 104 | 5 | 5 | 5 | 6 | Present |
| | | | | | | | invention |
| 5 | 103 | 106 | 5 | 5 | 5 | 6 | Present |
| | | | | | | | invention |
| 6 | 106 | 110 | 3 | 4 | 3 | 5 | Present |
| | | | | | | | invention |
| 7 | 106 | 110 | 3 | 6 | 3 | 6 | Present |
| | | | | | | | invention |
| 8 | 106 | 111 | 3 | 4 | 3 | 4 | Present |
| | | | | | | | invention |
| 9 | 107 | 112 | 3 | 3 | 3 | 3 | Present |
| | | | | | | | invention |
| 10 | 110 | 114 | 2 | 3 | 2 | 3 | Present |
| | | | | | | | invention |
| 11 | 111 | 114 | 2 | 2 | 2 | 2 | Present |
| | | | | | | | invention |
| 12 | 114 | 118 | 2 | 2 | 1 | 2 | Present |
| | | | | | | | invention |
| 13 | 114 | 118 | 2 | 2 | 1 | 2 | Present |
| | | | | | | | invention |
| 14 | 118 | 116 | 1 | 1 | 1 | 1 | Present |
| | | | | | | | invention |
| 15 | 120 | 120 | 1 | 1 | 1 | 1 | Present |
| | | | | | | | invention |
| 16 | 120 | 120 | 1 | 1 | 1 | 1 | Present |
| | | | | | | | invention |

From Table 2, it is found that the organic EL element of the present invention is excellent in power efficiency and light transmittance and is also excellent in bending resistance and high-temperature resistance. Less deterioration in these performance before and after bending and exposing to high temperature also indicates that the organic EL element of the present invention is excellent in gas barrier properties.

### INDUSTRIAL APPLICABILITY

According to the present invention, it is possible to obtain an organic electroluminescent element which is excellent in high-temperature resistance, bending resistance, and light transmittance, and this organic electroluminescent element can be suitably used in backlights for various displays, display plates such as signboards and emergency lights, and surface light emitters such as illumination light sources.

### REFERENCE SIGNS LIST

100, 101, 102 organic EL element

1A, 1B anti-reflection film

2A, 2B pressure-sensitive adhesive layer

3A, 3B antistatic layer

4 element substrate

5 sealing substrate

6A, 6B gas barrier layer

7A, 7B undercoat layer

8A, 8B transparent electrode

9 organic functional layer

1. A flexible organic electroluminescent element comprising an organic functional layer, which includes a light emitting layer interposed by a pair of transparent electrodes, between an element substrate and a sealing substrate,
wherein both the element substrate and the sealing substrate have a gas barrier layer, and
an anti-reflection film is laminated on the surface at a light emission side of at least one of the element substrate and the sealing substrate via a pressure-sensitive adhesive layer.

2. The organic electroluminescent element according to claim 1,
wherein at least one of the pair of transparent electrodes is a transparent electrode which includes an undercoat layer containing a nitrogen-containing compound and an electrode layer containing silver as a main component on the undercoat layer.

3. The organic electroluminescent element according to claim 2,
wherein the undercoat layer contains a compound satisfying a relation between interaction energies represented by the following Formula (1) and Formula (2).
ΔEef=n×ΔE/s Formula (1):
n: Number of nitrogen atom(s) (N) contained in compound and stably bonded with silver (Ag)
ΔE: Interaction energy between nitrogen atom (N) and silver (Ag)
s: Surface area of compound
−0.40≤ΔEef[kcal/mol·Å²]≤−0.10 Formula (2):

4. The organic electroluminescent element according to claim 1,
wherein at least one of the pair of transparent electrodes is a transparent electrode including a thin metal wire and a transparent conductive member.

5. The organic electroluminescent element according to claim 4,
wherein the thin metal wire contains metal nanoparticles.

6. The organic electroluminescent element according to claim 1,
wherein the anti-reflection film is laminated on the surfaces of the light emission sides of both of the element substrate and the sealing substrate via the pressure-sensitive adhesive layer.

7. The organic electroluminescent element according to claim 1,
wherein at least one of the gas barrier layers of the element substrate and the sealing substrate is two or more layers of the gas barrier layer, and
at least one layer of the two or more layers of the gas barrier layer is a gas barrier layer including a polysilazane modified layer.

8. The organic electroluminescent element according to claim 2,
wherein at least one of the pair of transparent electrodes is a transparent electrode including a thin metal wire and a transparent conductive member.

9. The organic electroluminescent element according to claim 2,
wherein the anti-reflection film is laminated on the surfaces of the light emission sides of both of the element substrate and the sealing substrate via the pressure-sensitive adhesive layer.

10. The organic electroluminescent element according to claim 2,
wherein at least one of the gas barrier layers of the element substrate and the sealing substrate is two or more layers of the gas barrier layer, and
at least one layer of the two or more layers of the gas barrier layer is a gas barrier layer including a polysilazane modified layer.

11. The organic electroluminescent element according to claim 3,
wherein at least one of the pair of transparent electrodes is a transparent electrode including a thin metal wire and a transparent conductive member.

12. The organic electroluminescent element according to claim 3,
wherein the anti-reflection film is laminated on the surfaces of the light emission sides of both of the element substrate and the sealing substrate via the pressure-sensitive adhesive layer.

13. The organic electroluminescent element according to claim 3,
wherein at least one of the gas barrier layers of the element substrate and the sealing substrate is two or more layers of the gas barrier layer, and
at least one layer of the two or more layers of the gas barrier layer is a gas barrier layer including a polysilazane modified layer.

14. The organic electroluminescent element according to claim 4,
wherein the anti-reflection film is laminated on the surfaces of the light emission sides of both of the element substrate and the sealing substrate via the pressure-sensitive adhesive layer.

15. The organic electroluminescent element according to claim 4,
wherein at least one of the gas barrier layers of the element substrate and the sealing substrate is two or more layers of the gas barrier layer, and
at least one layer of the two or more layers of the gas barrier layer is a gas barrier layer including a polysilazane modified layer.

16. The organic electroluminescent element according to claim 5,
wherein the anti-reflection film is laminated on the surfaces of the light emission sides of both of the element substrate and the sealing substrate via the pressure-sensitive adhesive layer.

17. The organic electroluminescent element according to claim 5,
wherein at least one of the gas barrier layers of the element substrate and the sealing substrate is two or more layers of the gas barrier layer, and
at least one layer of the two or more layers of the gas barrier layer is a gas barrier layer including a polysilazane modified layer.

18. The organic electroluminescent element according to claim 6,
wherein at least one of the gas barrier layers of the element substrate and the sealing substrate is two or more layers of the gas barrier layer, and
at least one layer of the two or more layers of the gas barrier layer is a gas barrier layer including a polysilazane modified layer.
